(19) United States
(12) Patent Application Publication
(10) Pub. No.: US 2022/0290965 A1
(43) Pub. Date: Sep. 15, 2022

(54) POSITION-SENSING CIRCUIT, POSITION-SENSING SYSTEM, MAGNET MEMBER, POSITION-SENSING METHOD, AND PROGRAM

(71) Applicant: Panasonic Intellectual Property Management Co., Ltd., Osaka (JP)

(72) Inventors: Noritaka ICHINOMIYA, Nara (JP); Kazuhiro ONAKA, Hyogo (JP)

(21) Appl. No.: 17/635,624

(22) PCT Filed: Aug. 13, 2020
(86) PCT No.: PCT/JP2020/030766

§ 371 Date: Feb. 15, 2022

(30) Foreign Application Priority Data
Aug. 27, 2019 (JP) 2019-155017
May 27, 2020 (JP) 2020-092590

(51) Int. Cl. G01B 7/00; G01R 33/09

(52) U.S. Cl. CPC G01B 7/003; G01R 33/093; G01R 33/091

(57) ABSTRACT

A position-sensing circuit includes a processing circuit. A magnet member includes a first track having a plurality of first magnetic poles and a second track having a plurality of second magnetic poles. A magnetic pole pitch between the plurality of first magnetic poles in a sensing direction is different from a magnetic pole pitch between the plurality of second magnetic poles in the sensing direction. A magnetic sensor includes a first sensor part configured to sense magnetism produced at the first track and a second sensor part configured to sense magnetism produced at the second track. The processing circuit is configured to determine, based on information on a phase of an output of the first sensor part and a phase of an output of the second sensor part, a position of the magnetic sensor with respect to the magnet member.

### TECHNICAL FIELD

The present disclosure generally relates to position-sensing circuits, position-sensing systems, magnet members, position-sensing methods, and programs and specifically relates to a position-sensing circuit configured to perform position sensing based on an output of a magnetic sensor, a position-sensing system, a magnet member, a position-sensing method, and a program.

### BACKGROUND ART

Patent Literature 1 describes a magnetic position detection device (a position-sensing system) including a magnetic scale, a magnetism sensing device, and a position calculation device. The magnetic scale includes a first magnetic scale and a second magnetic scale provided parallel to the first magnetic scale. The magnetism sensing device moves in a movement direction relative to the first magnetic scale and the second magnetic scale through magnetic fields formed respectively by the first magnetic scale and the second magnetic scale and measures using a plurality of magnetism sensing elements variation in the magnetic fields during the relative movement. The position calculation device calculates the absolute positions of the magnetism sensing elements on the magnetic scale from output values of the magnetism sensing elements, output by the magnetism sensing device.

In the magnetic position detection device described in Patent Literature 1, position detection resolution depends on an arrangement interval between the plurality of magnetism sensing elements. However, in the magnetic position detection device, a restriction resulting from the arrangement interval between the plurality of magnetism sensing elements and other reasons make an improvement in the position detection resolution difficult.

### CITATION LIST

### Patent Literature

Patent Literature 1: WO 2016/063417 A1

### SUMMARY OF INVENTION

It is an object of the present disclosure to provide a position-sensing circuit, a position-sensing system, a magnet member, a position-sensing method, and a program with improved position sensing resolution.

A position-sensing circuit according to an aspect of the present disclosure includes a processing circuit. The processing circuit is configured to process an output of a magnetic sensor. The magnetic sensor is configured to sense magnetism produced by a magnet member. The magnet member includes a first track having a plurality of first magnetic poles and a second track having a plurality of second magnetic poles. The plurality of first magnetic poles are magnetic poles exhibiting N polarity and magnetic poles exhibiting S polarity which are alternately aligned in a sensing direction which is prescribed. The plurality of second magnetic poles are magnetic poles exhibiting N polarity and magnetic poles exhibiting S polarity which are alternately aligned in the sensing direction. A magnetic pole pitch of the plurality of first magnetic poles in the sensing direction is different from a magnetic pole pitch of the plurality of second magnetic poles in the sensing direction. The magnetic sensor includes a first sensor part configured to sense magnetism produced at the first track and a second sensor part configured to sense magnetism produced at the second track. At least one of the magnetic sensor or the magnet member is configured to move along the sensing direction relative to the other of the magnetic sensor or the magnet member. The processing circuit is configured to determine, based on information on a phase of an output of the first sensor part and a phase of an output of the second sensor part, a position of the magnetic sensor relative to the magnet member.

A position-sensing system according to an aspect of the present disclosure includes the position-sensing circuit, the magnet member, and the magnetic sensor.

A magnet member according to an aspect of the present disclosure is included in the position-sensing system.

A position-sensing method according to an aspect of the present disclosure includes a processing step. The processing step includes processing an output of a magnetic sensor. The magnetic sensor is configured to sense magnetism produced by a magnet member. The magnet member includes a first track having a plurality of first magnetic poles and a second track having a plurality of second magnetic poles. The plurality of first magnetic poles are magnetic poles exhibiting N polarity and magnetic poles exhibiting S polarity which are alternately aligned in a sensing direction which is prescribed. The plurality of second magnetic poles are magnetic poles exhibiting N polarity and magnetic poles exhibiting S polarity which are alternately aligned in the sensing direction. A magnetic pole pitch of the plurality of first magnetic poles in the sensing direction is different from a magnetic pole pitch of the plurality of second magnetic poles in the sensing direction. The magnetic sensor includes a first sensor part configured to sense magnetism produced at the first track and a second sensor part configured to sense magnetism produced at the second track. At least one of the magnetic sensor or the magnet member is configured to move along the sensing direction relative to the other of the magnetic sensor or the magnet member. The processing step includes determining, based on information on a phase of an output of the first sensor part and a phase of an output of the second sensor part, a position of the magnetic sensor relative to the magnet member.

A program according to an aspect of the present disclosure is a program configured to cause one or more processors to execute the position-sensing method.

### BRIEF DESCRIPTION OF DRAWINGS

FIG. 1 is a plan view of a position-sensing system according to a first embodiment;

FIGS. 2A and 2B are circuit diagrams of a magnetic sensor of the position-sensing system;

FIGS. 3A and 3B are graphs of signals processed by the position-sensing system;

FIG. 4 is a side view of a main part of the magnetic sensor of the position-sensing system;

FIG. 5 is a flowchart schematically illustrating a procedure of position sensing by the position-sensing system;

FIG. 6 is a graph of a signal processed by the position-sensing system;

FIG. 7 is a plan view of a position-sensing system according to a second variation of the first embodiment;

FIG. 8 is a plan view of a position-sensing system according to a third variation of the first embodiment;

FIG. 9 is a graph of an example of a sensing result by the position-sensing system of the third variation;

FIG. 10 is a perspective view of a position-sensing system according to a fourth variation of the first embodiment;

FIG. 11 is a plan view of a position-sensing system according to a second embodiment;

FIG. 12 is a plan view of the position-sensing system of the second embodiment, where a magnet member is rotated halfway from a state shown in FIG. 11; and

FIGS. 13A to 13C are graphs of signals processed by the position-sensing system of the second embodiment.

### DESCRIPTION OF EMBODIMENTS

Position-sensing circuits, position-sensing systems, and magnet members of embodiments will be described below with reference to the drawings. Note that the embodiments described below are mere examples of various embodiments of the present disclosure. Various modifications may be made to the following embodiments depending on design and the like as long as the object of the present disclosure is achieved. Moreover, figures described in the following embodiments are schematic views, and therefore, the ratio of sizes and the ratio of thicknesses of components in the drawings do not necessarily reflect actual dimensional ratios.

### First Embodiment

(1) Overview

A position-sensing system 1 senses the position of a sensing target based on magnetism. The position-sensing system 1 is used, for example, as a position sensor such as a linear encoder or a rotary encoder. More specifically, the position-sensing system 1 is used, for example, as a position sensor (an encoder) for sensing the position of a motor (a linear motor or a rotary motor) for driving a lens or the like of a camera. Moreover, the position-sensing system 1 is used, for example, as a position sensor for sensing the position of a brake pedal, a brake lever, or a shift lever of an automobile. Alternatively, the position-sensing system 1 is used as a device for reading signs written by magnetic substances. However, the application of the position-sensing system 1 is not limited to these examples. Moreover, the “position” to be sensed by the position-sensing system 1 represents a concept including both the coordinate of a sensing target and the angle of rotation of the sensing target (the orientation of the sensing target) around a rotation axis (a virtual axis) extending through the sensing target. That is, the position-sensing system 1 senses at least one of the coordinate of the sensing target or the angle of rotation of the sensing target.

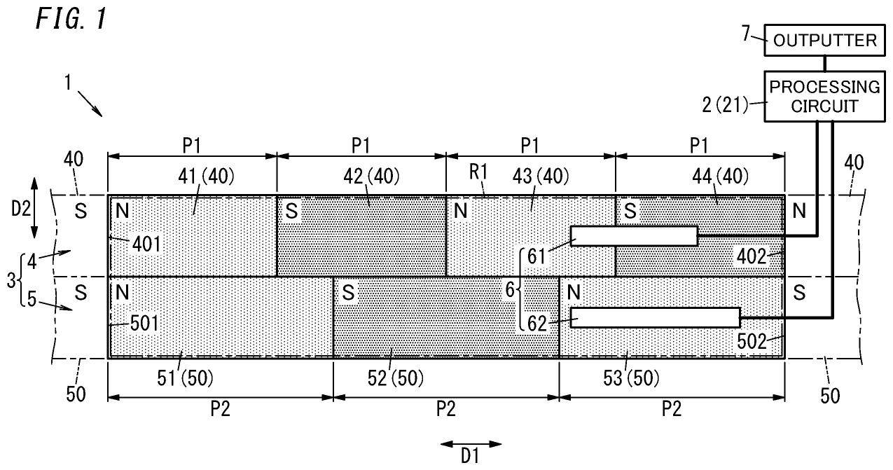

As shown in FIG. 1, the position-sensing system 1 of the present embodiment includes a position-sensing circuit 2, a magnet member 3, and a magnetic sensor 6. The position-sensing circuit 2 includes a processing circuit 21. The processing circuit 21 processes an output of the magnetic sensor 6. The magnetic sensor 6 senses magnetism produced by the magnet member 3.

The magnet member 3 includes a first track 4 and a second track 5. The first track 4 includes a plurality of first magnetic poles 40. The second track 5 includes a plurality of second magnetic poles 50. The plurality of first magnetic poles 40 are magnetic poles exhibiting N polarity and magnetic poles exhibiting S polarity which are alternately aligned in a sensing direction D1 which is prescribed. The plurality of second magnetic poles 50 are magnetic poles exhibiting N polarity and magnetic poles exhibiting S polarity which are alternately aligned in the sensing direction D1. The first track 4 and the second track 5 face each other in a direction D2 orthogonal to the sensing direction D1. A magnetic pole pitch P1 of the plurality of first magnetic poles 40 in the sensing direction D1 is different from a magnetic pole pitch P2 of the plurality of second magnetic poles 50 in the sensing direction D1.

The magnetic sensor 6 includes a first sensor part 61 and a second sensor part 62. The first sensor part 61 senses magnetism produced at the first track 4. The second sensor part 62 senses magnetism produced at the second track 5. At least one of the magnetic sensor 6 or the magnet member 3 moves along the sensing direction D1 relative to the other of the magnetic sensor 6 or the magnet member 3.

The processing circuit 21 is configured to determine, based on information on a phase of an output of the first sensor part 61 and a phase of an output of the second sensor part 62, the position of the magnetic sensor 6 relative to the magnet member 3.

In the position-sensing system 1 and the position-sensing circuit 2 of the present embodiment, the position sensing resolution is improved more than in the case where the processing circuit 21 performs position sensing without referring to the information on the phase of the output of the first sensor part 61 and the phase of the output of the second sensor part 62.

Moreover, the magnetic sensor 6 includes at least two sensor parts, namely, the first sensor part 61 and the second sensor part 62. Thus, the number of sensor parts can be reduced.

(2) Configuration

The position-sensing system 1, the position-sensing circuit 2, and the magnet member 3 will be described in more detail below.

As described above, at least one of the magnetic sensor 6 or the magnet member 3 moves along the sensing direction D1 relative to the other of the magnetic sensor 6 or the magnet member 3. In the present embodiment, an example in which of the magnetic sensor 6 and the magnet member 3, the magnetic sensor 6 moves along the sensing direction D1 relative to the magnet member 3 will be described. That is, the magnetic sensor 6 of the present embodiment is attached to, or integrated into, a sensing target whose position is to be sensed.

The position-sensing system 1 of the present embodiment is used as an absolute encoder (a linear encoder). That is, the position-sensing system 1 senses the absolute position of the magnetic sensor 6 relative to the magnet member 3.

(2-1) Magnet Member

As the shape of the magnet member 3, for example, a linear shape, an arc shape, or an annular shape may be adopted. A typical example of the arc shape is a circular arc or an elliptical arc. A typical example of the annular shape is a circular ring or an elliptical ring. In the present embodiment, an example in which the shape of the magnet member 3 is a linear shape will be described. The magnet member 3 has a length in the sensing direction D1. That is, the shape of the magnet member 3 is a linear shape along the sensing direction D1.

In the magnet member 3, the first track 4 and the second track 5 are formed as one piece. In FIG. 1, the first track 4 and the second track 5 are shown as if the first track 4 and the second track 5 were in contact with each other, but in practice, the first track 4 and the second track 5 are arranged with a prescribed space provided therebetween. Note that the first track 4 and the second track 5 may be in contact with each other. The first track 4 and the second track 5 each have a length in the sensing direction D1. The first track 4 and the second track 5 are formed by, for example, printing magnetic ink onto a sheet-like base material.

The first track 4 and the second track 5 face each other in the direction D2 orthogonal to the sensing direction D1. Moreover, both the longitudinal direction of the first track 4 and the longitudinal direction of the second track 5 are along the sensing direction D1. In other words, the second track 5 is provided parallel to the first track 4.

The first track 4 includes the plurality of first magnetic poles 40. The second track 5 includes the plurality of second magnetic poles 50.

The plurality of first magnetic poles 40 are magnetic poles exhibiting N polarity and magnetic poles exhibiting S polarity which are alternately aligned in a sensing direction D1. The plurality of second magnetic poles 50 are magnetic poles exhibiting N polarity and magnetic poles exhibiting S polarity which are alternately aligned in the sensing direction D1. In FIG. 1, the magnetic poles exhibiting N polarity are denoted by the alphabet “N”, and the magnetic poles exhibiting S polarity are denoted by the alphabet S. The first magnetic poles 40 are equal to each other in length in the sensing direction D1. The second magnetic poles 50 are equal to each other in length in the sensing direction D1. In the present disclosure, “equal” is not limited to referring to the case where a plurality of values are exactly equal to each other but may also refer to the case where a plurality of values differ from each other within an allowable error range.

The magnetic pole pitch P1 of the plurality of first magnetic poles 40 in sensing direction D1 has, for example, a value within a range from 0.1 mm to 1 mm. In this embodiment, the magnetic pole pitch P1 of the plurality of first magnetic poles 40 is defined as described below. That is, when the plurality of first magnetic poles 40 are tracked toward one side in the sensing direction D1 (e.g., rightward when the sensing direction D1 is defined as the left/right direction), the distance from one end, at the one side, of a first magnetic pole 40 to one end of another first magnetic pole 40 adjacent to the first magnetic pole 40 is the magnetic pole pitch P1. Note that the magnetic pole pitch P1 may be defined as an average value of the distances between the first magnetic poles 40. In the present embodiment, no gap is provided between the plurality of first magnetic poles 40, and therefore, the magnetic pole pitch P1 is equal to the length of each first magnetic pole 40 in the sensing direction D1. Between the plurality of first magnetic poles 40, a gap may be provided.

The magnetic pole pitch P2 of the plurality of second magnetic poles 50 in sensing direction D1 has, for example, a value within a range from 0.1 mm to 1 mm. In this embodiment, the magnetic pole pitch P2 of the plurality of second magnetic poles 50 is defined as described below. That is, when the plurality of second magnetic poles 50 are tracked toward one side in the sensing direction D1 (e.g., rightward when the sensing direction D1 is defined as the left/right direction), the distance from one end, at the one side, of a second magnetic pole 50 to one end of another second magnetic pole 50 adjacent to the second magnetic pole 50 is the magnetic pole pitch P2. Note that the magnetic pole pitch P2 may be defined as an average value of the distances between the second magnetic poles 50. In the present embodiment, no gap is provided between the plurality of second magnetic poles 50, and therefore, the magnetic pole pitch P2 is equal to the length of each second magnetic pole 50 in the sensing direction D1. Between the plurality of second magnetic poles 50, a gap may be provided.

The magnet member 3 has a detection region R1 which is to face the magnetic sensor 6. The detection region R1 in the present embodiment is a rectangular region. The magnetic sensor 6 moves along the sensing direction D1 relative to the magnet member 3 at least within a region facing the detection region R1. The range of movement of the magnetic sensor 6 of the present embodiment is limited such that at least part of the magnetic sensor 6 is kept facing the detection region R1. In FIG. 1, part of the magnet member 3 outside the detection region R1 is indicated by a long dashed double-short dashed line, but the part of the magnet member 3 outside the detection region R1 is also physical part of the magnet member 3.

In the following description, the number of magnetic poles, which are disposed in the detection region R1, of the plurality of first magnetic poles 40 is referred to as a first magnetic pole number. In the present embodiment, the first magnetic pole number is four. Moreover, in the following description, the number of magnetic poles, which are disposed in the detection region R1, of the plurality of second magnetic poles 50 is referred to as a second magnetic pole number. In the present embodiment, the second magnetic pole number is three. That is, the magnet member 3 includes the first magnetic pole number of first magnetic poles 40 and the second magnetic pole number of second magnetic poles 50 within the detection region R1. The first magnetic pole number and the second magnetic pole number are different from each other. The first magnetic pole number and the second magnetic pole number are coprime.

Moreover, the first magnetic pole number and the second magnetic pole number are numbers close to each other. In an example, “the first magnetic pole number and the second magnetic pole number are numbers close to each other” means that the difference between the first magnetic pole number and the second magnetic pole number is smaller than a smaller one of the first magnetic pole number and the second magnetic pole number. In another example, “the first magnetic pole number and the second magnetic pole number are numbers close to each other” means that the difference between the first magnetic pole number and the second magnetic pole number is less than or equal to one, less than or equal to two, or less than or equal to three. In still another example, “the first magnetic pole number and the second magnetic pole number are numbers close to each other” means that the difference between the first magnetic pole number and the second magnetic pole number is less than or equal to 50%, 40%, or 30% of a larger magnetic pole number of the first magnetic pole number and the second magnetic pole number.

As the dimension of the second magnetic pole 50 with respect to the dimension of the first magnetic pole 40 increases, the influence of the second magnetic pole 50 over the magnetism surrounding the first magnetic pole 40 increases. Moreover, as the dimension of the first magnetic pole 40 with respect to the dimension of the second magnetic pole 50 increases, the influence of the first magnetic pole 40 over the magnetism surrounding the second magnetic pole 50 increases. In the present embodiment, the first magnetic pole number and the second magnetic pole number are numbers close to each other, and therefore, the difference between the dimension of the first magnetic pole 40 and the dimension of the second magnetic pole 50 is small. This reduces the influence of first magnetic pole 40 and the second magnetic pole 50 over each other. This improves the accuracy of position sensing by the position-sensing system 1.

Within the detection region R1, two or more first magnetic poles 40 and two or more second magnetic poles 50 are preferably arranged. That is, the first magnetic pole number and the second magnetic pole number are each preferably larger than or equal to two. Note that if at least part of the first magnetic pole 40 or the second magnetic pole 50 is disposed within the detection region R1, the magnetic pole is deemed to be disposed within the detection region R1.

Both ends (a first end 401 and a second end 402) in the sensing direction D1 of the first magnetic pole number of first magnetic poles 40 within the detection region R1 overlap both ends of the detection region R1 in the sensing direction D1. Both ends (a first end 501 and a second end 502) in the sensing direction D1 of the second magnetic pole number of second magnetic poles 50 within the detection region R1 overlap both the ends of the detection region R1 in the sensing direction D1.

Thus, the first magnetic pole number of first magnetic poles 40 and the second magnetic pole number of second magnetic poles 50 within the detection region R1 are arranged such that the positions of the first ends 401 and 501 respectively of the first magnetic poles 40 and the second magnetic poles 50 in the sensing direction D1 are aligned with each other. That is, the first ends 401 and 501 respectively of the first magnetic pole number of first magnetic poles 40 and the second magnetic pole number of second magnetic poles 50 are aligned with each other in the second direction D2 orthogonal to the sensing direction D1. Moreover, the first magnetic pole number of first magnetic poles 40 and the second magnetic pole number of second magnetic poles 50 are arranged such that the positions of the second ends 402 and 502 respectively of the first magnetic poles 40 and the second magnetic poles 50 in the sensing direction D1 are aligned with each other. That is, the second ends 402 and 502 respectively of the first magnetic pole number of first magnetic poles 40 and the second magnetic pole number of second magnetic poles 50 are aligned with each other in the second direction D2 orthogonal to the sensing direction D1.

Description given below is focused on only the first magnetic pole number of (four) first magnetic poles 40, disposed within the detection region R1, of the plurality of first magnetic poles 40 unless otherwise noted. Moreover, the description given below is focused on only the second magnetic pole number of (three) second magnetic poles 50, disposed within the detection region R1, of the plurality of second magnetic poles 50 unless otherwise noted.

In this embodiment, the four first magnetic poles 40 are distinguished from one another, and the four first magnetic poles 40 are referred to as first magnetic poles 41, 42, 43, and 44. The four first magnetic poles 41, 42, 43, and 44 are aligned in this order in the sensing direction D1. In the first track 4 of the present embodiment, the first magnetic poles 41 and 43 are magnetic poles exhibiting N polarity, and the first magnetic poles 42 and 44 are magnetic poles exhibiting S polarity.

Moreover, in this embodiment, the three second magnetic poles 50 are distinguished from one another, and the three second magnetic poles 50 are referred to as second magnetic poles 51, 52, and 53. The three second magnetic poles 51, 52, and 53 are aligned in this order in the sensing direction D1. In the second track 5 of the present embodiment, the second magnetic poles 51 and 53 are magnetic poles exhibiting N polarity, and the second magnetic pole 52 is a magnetic pole exhibiting S polarity.

Within the detection region R1, the length of the first track 4 in the sensing direction D1 is equal to the length of the second track 5 in the sensing direction D1. That is, the relationship among the magnetic pole pitch P1, the first magnetic pole number (four), the magnetic pole pitch P2, and the second magnetic pole number (three) is defined as: P1×(First Magnetic Pole Number)=P2×(Second Magnetic Pole Number). The magnetic pole pitch P1 is shorter than the magnetic pole pitch P2.

(2-2) Magnetic Sensor

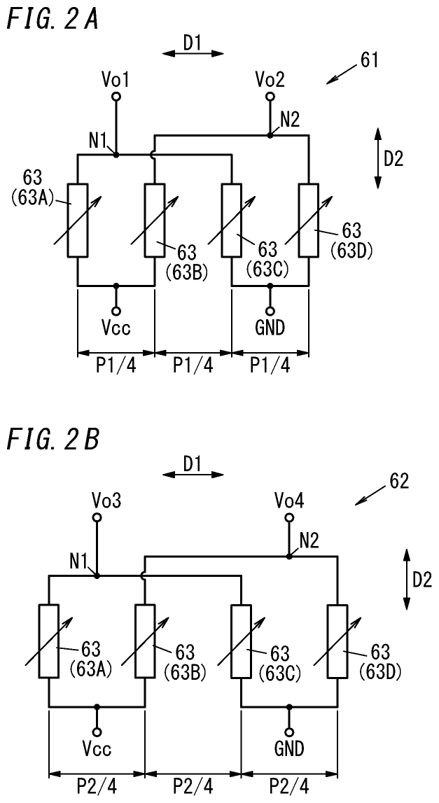

The magnetic sensor 6 includes the first sensor part 61 and the second sensor part 62. The first sensor part 61 and the second sensor part 62 are together movable in the sensing direction D1. The first sensor part 61 and the second sensor part 62 are housed in, for example, an identical package such that the first sensor part 61 and the second sensor part 62 are together movable in the sensing direction D1. Each of the first sensor part 61 and the second sensor part 62 of the present embodiment includes an artificial lattice-type Giant Magneto Resistive effect (GMR) element 63. More specifically, as shown in FIGS. 2A and 2B, the first sensor part 61 and the second sensor part 62 each have four GMR elements 63. The four GMR elements 63 are in a bridge configuration. That is, two series circuits each including two GMR elements 63 are connected between a power supply (Vcc) and ground (GND). The two series circuits are connected parallel to each other. One series circuit of the two series circuits outputs a first voltage between its two GMR elements 63. In the following description, the first voltage at the first sensor part 61 is referred to as a first voltage Vo1, and the first voltage at the second sensor part 62 is referred to as a first voltage Vo3. The other series circuit of the two series circuits outputs a second voltage between its two GMR elements 63. In the following description, the second voltage at the first sensor part 61 is referred to as a second voltage Vo2, and the second voltage at the second sensor part 62 is referred to as a second voltage Vo4.

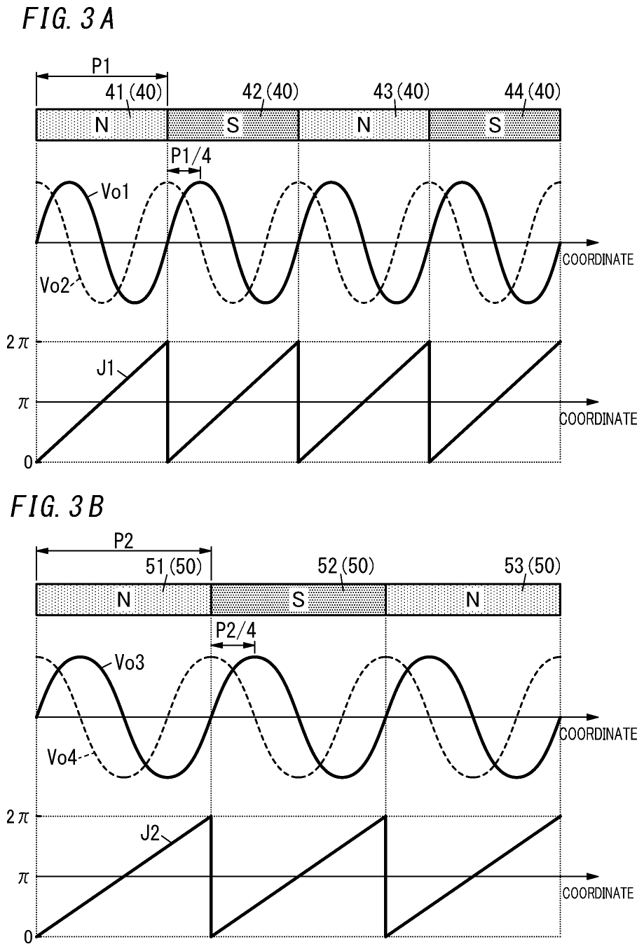

The four GMR elements 63 of the first sensor part 61 are aligned in the sensing direction D1, and the interval between the GMR elements 63 corresponds to 1/4 times the magnetic pole pitch P1. The four GMR elements 63 of the second sensor part 62 are aligned in the sensing direction D1, and the interval between the GMR elements 63 corresponds to 1/4 times the magnetic pole pitch P2. More specifically, the two GMR elements 63 (also denoted by 63A and 63C in FIG. 2A or 2B) are arranged at an interval 1/2 times the magnetic pole pitch P1 (or P2). The two GMR elements 63A and 63C are connected to each other in series. A node N1 between the two GMR elements 63A and 63C is electrically connected to an output terminal of the first voltage Vo1 (or Vo3). The two GMR elements 63 (also denoted by 63B and 63D in FIG. 2A or 2B) are arranged at an interval 1/2 times the magnetic pole pitch P1 (or P2). The two GMR elements 63B and 63D are connected to each other in series. A node N2 between the two GMR elements 63B and 63D is electrically connected to an output terminal of the second voltage Vo2 (or Vo4). The GMR element 63B is disposed at a spatially middle location between the GMR elements 63A and 63C. The GMR element 63C is disposed at a spatially middle location between the GMR elements 63B and 63D. Such an arrangement results in that in each of the first sensor part 61 and the second sensor part 62, the first voltage Vo1 and the second voltage Vo2 are different in phase by P1/4 (see the middle section in FIG. 3A). Similarly, the first voltage Vo3 and the second voltage Vo4 are different in phase by P2/4 (see the middle section in FIG. 3B). Of the orthogonal coordinate systems in the middle sections in FIGS. 3A and 3B, the abscissas represent coordinates respectively of the first sensor part 61 and the second sensor part 62 in the sensing direction D1, and the ordinates represents the outputs (the voltages) of the first sensor part 61 and the second sensor part 62, respectively.

As shown in FIG. 1, the first sensor part 61 is disposed to be adjacent to the first track 4. As used herein, “adjacent” refers to a concept including a state where a plurality of members located close to each other are in contact with each other and a state where a plurality of members located close to each other are separate from each other. The first sensor part 61 senses magnetism produced at the first track 4. The second sensor part 62 is disposed to be adjacent to the second track 5. The second sensor part 62 senses magnetism produced at the second track 5.

The first sensor part 61 and the second sensor part 62 move in the sensing direction D1 relative to the magnet member 3, thereby changing the positional relationship between the magnet member 3 and each of the first sensor part 61 and the second sensor part 62, which changes the orientations of the magnetic fields at the locations of the first sensor part 61 and the second sensor part 62. In accordance with the change in the orientation of the magnetic field at the first sensor part 61, the electric resistances of the GMR elements 63 change, thereby changing the first voltage Vo1 and the second voltage Vo2. Similarly, in accordance with the change in the orientation of the magnetic field at the second sensor part 62, the electric resistance of the GMR elements 63 change, thereby changing the first voltage Vo3 and the second voltage Vo4. In sum, the first sensor part 61 outputs the first voltage Vo1 and the second voltage Vo2 according to the position of the first sensor part 61, and the second sensor part 62 outputs the first voltage Vo3 and the second voltage Vo4 corresponding to the position of the second sensor part 62.

In the orthogonal coordinate system shown in the middle section in FIG. 3A, the coordinate axis (the abscissa) representing the coordinate of the first sensor part 61 in the sensing direction D1 is orthogonal to the coordinate axis (the ordinate) representing the output (the voltages) of the first sensor part 61. In the orthogonal coordinate system shown in the middle section in FIG. 3B, the coordinate axis (the abscissa) representing the coordinate of the second sensor part 62 in the sensing direction D1 is orthogonal to the coordinate axis (the ordinate) representing the output (the voltages) of the second sensor part 62. In the orthogonal coordinate systems, the output waveforms of the first sensor part 61 and the second sensor part 62 are each sinusoidal. That is, the waveform of each of the first voltage Vo1 (or Vo3) and the second voltage Vo2 (or Vo4) in the orthogonal coordinate systems is sinusoidal.

In FIG. 3A, the first magnetic pole number of first magnetic poles 40 are shown in accordance with the coordinates of the first sensor part 61 in the sensing direction D1. In this embodiment, the coordinate of the first sensor part 61 in the sensing direction D1 refers to, for example, a coordinate of one end (in FIG. 3A, the left end) of the first sensor part 61 in the sensing direction D1. Similarly, in FIG. 3B, the second magnetic pole number of second magnetic poles 50 are shown in accordance with the coordinates of the second sensor part 62 in the sensing direction D1. In this embodiment, the coordinate of the second sensor part 62 in the sensing direction D1 refers to, for example, a coordinate of one end (in FIG. 3B, the left end) of the second sensor part 62 in the sensing direction D1. The first sensor part 61 and the second sensor part 62 move in the sensing direction D1 with the coordinate of the first sensor part 61 coinciding with the coordinate of the second sensor part 62 in the sensing direction D1.

The magnitudes of the outputs of the first sensor part 61 and the second sensor part 62 when the magnetic field is oriented in one direction, are respectively equal to the magnitudes of the outputs of the first sensor part 61 and the second sensor part 62 when the magnetic field is oriented in a direction opposite to the one direction. While the first sensor part 61 moves in the sensing direction D1 by a distance equal to the magnetic pole pitch P1, the orientation (the angle) of the magnetic field at the first sensor part 61 changes by 180 degrees, and therefore, the first voltage Vo1 and the second voltage Vo2 change by one cycle. Similarly, while the second sensor part 62 moves in the sensing direction D1 by a distance equal to the magnetic pole pitch P2, the orientation (the angle) of the magnetic field at the second sensor part 62 changes by 180 degrees, and therefore, the first voltage Vo3 and the second voltage Vo4 change by one cycle.

(2-2-1) Structure of GMR Element

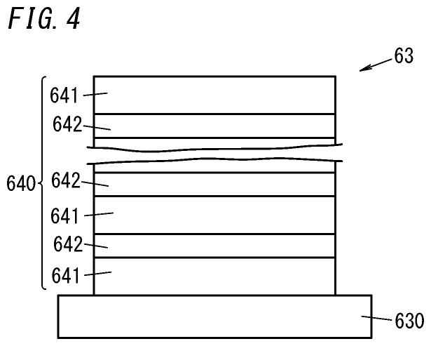

FIG. 4 schematically shows the structure of the GMR element 63. The GMR element 63 includes a substrate 630 and a layered structure 640 formed on the substrate 630. The substrate 630 is, for example, a silicon substrate. This reduces cost and size. The layered structure 640 includes, for example, cobalt and iron.

The layered structure 640 is more specifically a layered structure of metal. The thickness of each layer is about several nanometers. About several tens of atoms per layer are stacked in the thickness direction defined with respect to the layered structure.

The layered structure 640 includes magnetic layers 641 and non-magnetic layers 642 alternately stacked on one another. That is, the layered structure 640 has a spin valve structure. The number of layers constituting the layered structure 640 is, for example, larger than or equal to 10 or larger than or equal to 20. Each magnetic layer 641 is a ferromagnetic layer. The magnetic layers 641 are more easily magnetized than the non-magnetic layers 642. Each magnetic layer 641 includes, for example, cobalt and iron. In an example, the composition ratio of the cobalt is equal to the composition ratio of the iron. Each non-magnetic layer 642 is a layer of a non-magnetic substance. Each non-magnetic layer 642 includes, for example, copper.

Conventionally, nickel may be adopted as a magnetic material included in the magnetic layers 641 of the layered structure 640. However, the layered structure 640 preferably includes no nickel. This is because when the layered structure 640 is subjected to heat, nickel is diffused into copper and the like in the layered structure 640, and as a result, the layered structure 640 may no longer be able to maintain its structure. Inclusion of no nickel in the layered structure 640 results in improved heat resistance of the layered structure 640 (the magnetic sensor 6). Moreover, inclusion of cobalt and iron in the magnetic layer 641 results in a relatively large output of the GMR element 63. The magnetic layer 641 preferably includes only cobalt and iron.

Further, inclusion of copper in each non-magnetic layer 642 results in a relatively large output of the GMR element 63, and in addition, results in a relatively small degree of hysteresis of a change in the electric resistance of the GMR element 63 with respect to a change in magnetism. Each non-magnetic layer 642 preferably includes only copper.

(3) Processing Circuit

As shown in FIG. 1, the position-sensing circuit 2 of the present embodiment includes only the processing circuit 21. The processing circuit 21 includes a computer system including one or more processors and memory. At least some of the functions of the processing circuit 21 are performed by making the processor(s) of the computer system execute a program(s) stored in the memory of the computer system. The program(s) may be stored in the memory. The program(s) may also be downloaded via a telecommunications network such as the Internet or distributed after having been stored in a non-transitory storage medium such as a memory card.

The processing circuit 21 determines, based on the output (the first voltage Vo1 and the second voltage Vo2) of the first sensor part 61 and the output (the first voltage Vo3 and the second voltage Vo4) of the second sensor part 62, the position of the magnetic sensor 6 relative to the magnet member 3. More specifically, the processing circuit 21 determines, based on information on a phase of the output of the first sensor part 61 and a phase of the output of the second sensor part 62, the position of the magnetic sensor 6 relative to the magnet member 3. The position of the magnetic sensor 6 is at least defined as any one point of the magnetic sensor 6. In this embodiment, for example, the position of the magnetic sensor 6 is defined as the position of one end (in FIG. 1, the left end) of the first sensor part 61 in the sensing direction D1.

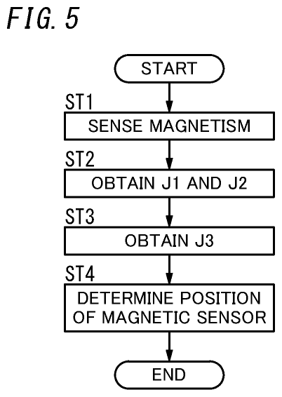

Procedures of position sensing by the position-sensing system 1 will be briefly explained with reference to FIG. 5. First of all, each of the first sensor part 61 and the second sensor part 62 of the magnetic sensor 6 senses magnetism (step ST1). Then, the processing circuit 21 obtains, based on the output of the first sensor part 61, a first determination value J1, and obtains, based on the output of the second sensor part 62, a second determination value J2 (step ST2). The first determination value J1 is a value corresponding to the phase of the output of the first sensor part 61, and the second determination value J2 is a value corresponding to the phase of the output of the second sensor part 62. The processing circuit 21 further obtains a third determination value J3 corresponding to the difference between the first determination value J1 and the second determination value J2 (step ST3). Then, the processing circuit 21 determines, based on the third determination value J3, the position of the magnetic sensor 6 relative to the magnet member 3 (step ST4). More details will be described below.

First of all, the processing circuit 21 receives, as shown in the middle sections in FIGS. 3A and 3B, the first voltages Vo1 and Vo3 and the second voltages Vo2 and Vo4 which each have a sinusoidal waveform. Then, the processing circuit 21 obtains the first determination value J1 using (Formula 1) indicated below and obtains the second determination value J2 using (Formula 2) indicated below.

J1=arctan(Vo1/Vo2) (Vo1>0, Vo2>0),

J1=arctan(Vo1/Vo2)+π(Vo2<0),

J1=arctan(Vo1/Vo2)+π2((Vo1<0, Vo2>0) (Formula 1)

J2=arctan(Vo3/Vo4) (Vo3>0, Vo4>0),

J2=arctan(Vo3/Vo4)+π(Vo4<0),

J2=arctan(Vo3/Vo4)+2π(Vo3<0, Vo4>0) (Formula 2)

When the first voltage Vo1 is a sine wave and the second voltage Vo2 is a sine wave with a phase leading the phase of the first voltage Vo1 by P1/4 (here, P1 is normalized to P1=2π), the first determination value J1 matches the phase (phase is greater than or equal to 0 and less than 2π) of the first voltage Vo1. When the second voltage Vo2 is regarded as a cosine wave of the same phase as the first voltage Vo1, the first determination value J1 also matches the phase (phase is greater than or equal to 0 and less than 2π) of the second voltage Vo2 as the cosine wave.

When the first voltage Vo3 is a sine wave and the second voltage Vo4 is a sine wave with a phase leading the phase of the first voltage Vo3 by P2/4 (here, P2 is normalized to P2=2π), the second determination value J2 matches the phase (phase is greater than or equal to 0 and less than 2π) of the first voltage Vo3. When the second voltage Vo4 is regarded as a cosine wave of the same phase as the first voltage Vo3, the second determination value J2 also matches the phase (phase is greater than or equal to 0 and less than 2π) of the second voltage Vo4 as the cosine wave.

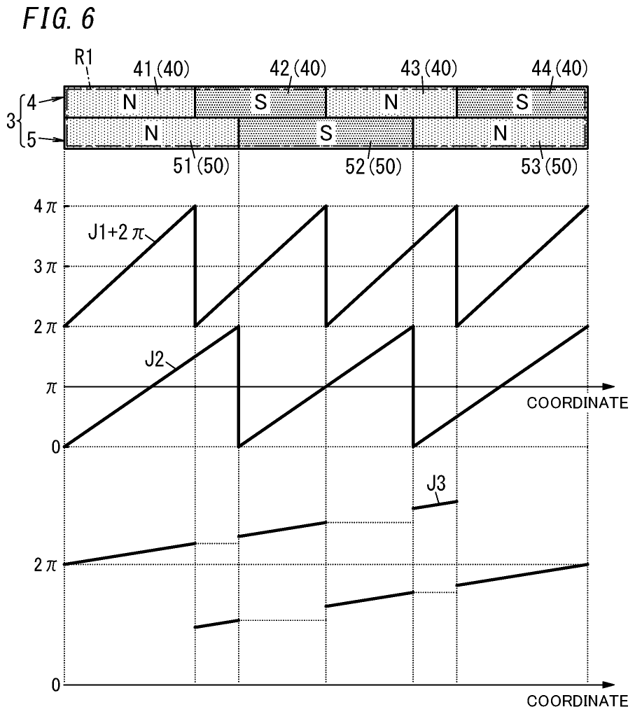

In the lower section in FIGS. 3A and 3B and in the middle section in FIG. 6, the first determination value J1 and the second determination value J2 are shown. In the orthogonal coordinate system shown in the lower section in FIG. 3A, the coordinate axis (the abscissa) representing the coordinate of the first sensor part 61 in the sensing direction D1 is orthogonal to the coordinate axis (the ordinate) representing the first determination value J1. In the orthogonal coordinate system shown in the lower section in FIG. 3B, the coordinate axis (the abscissa) representing the coordinate of the second sensor part 62 in the sensing direction D1 is orthogonal to the coordinate axis (the ordinate) representing the second determination vale J2. In the orthogonal coordinate system shown in the middle section in FIG. 6, the coordinate axis (the abscissa) representing the coordinates of the first sensor part 61 and the second sensor part 62 in the sensing direction D1 is orthogonal to the coordinate axis (the ordinate) representing the first determination value J1 and the second determination value J2. In the orthogonal coordinate systems shown in the lower sections in FIGS. 3A and 3B and in the middle section in FIG. 6, each of the first determination value J1 and the second determination value J2 has a sawtooth waveform. More specifically, as the coordinate in the sensing direction D1 changes over the distance between both ends of each magnetic pole (each first magnetic pole 40 and each second magnetic pole 50), the first determination value J1 and the second determination value J2 linearly change. Then, the same waveform is repeated for each of the intervals (the magnetic pole pitches P1 and P2) between both the ends of each magnetic pole. That is, in the magnetic pole pitch P1, the first determination value J1 monotonously increases (or decreases). Thus, the first determination value J1 differs at any two points in the magnetic pole pitch P1. Moreover, in the magnetic pole pitches P2, the second determination value J2 monotonously increases (or decreases). Thus, the second determination value J2 differs at any two points in the magnetic pole pitch P2.

The processing circuit 21 further obtains, as the third determination value J3, a value corresponding to the difference between the first determination value J1 and the second determination value J2. That is, the third determination value J3 is a value corresponding to the difference between the first determination value J1 based on the output of the first sensor part 61 and the second determination value J2 based on the output of the second sensor part 62, and the processing circuit 21 determines, based on the third determination value J3, the position of the magnetic sensor 6 relative to the magnet member 3. The third determination value J3 is obtained, for example, using (Formula 3) indicated below.

J3=J1−J2+2π (Formula 3)

The difference between (J1+2π) and the second determination value J2 in the middle section in FIG. 6 is equal to the third determination value J3 in the lower section in FIG. 6. Note that to facilitate the explanation, the third determination value J3 has been obtained using (Formula 3) in the description above, but in practice, the third determination value J3 may be obtained using (Formula 4) indicated below.

J3=J1−J2 (Formula 4)

The third determination value J3 may be obtained using either (Formula 3) or (Formula 4). In accordance with which of (Formula 3) or (Formula 4) is used to obtain the third determination value J3, an arithmetic equation, a data table, or the like representing the relationship between the third determination value J3 and the position of the magnetic sensor 6 is accordingly set.

In the orthogonal coordinate system shown in the lower section in FIG. 6, the coordinate axis (abscissa) representing the coordinates of the first sensor part 61 and the second sensor part 62 in the sensing direction D1 is orthogonal to the coordinate axis (ordinate) representing the third determination value J3. In FIG. 6, dotted lines are projection lines but are not lines representing the first to third determination values J1 to J3. As shown in the lower section in FIG. 6, when the range of movement of the magnetic sensor 6 is limited within the region facing the detection region R1, the third determination value J3 is different for each position in a substantially entire range of movement of the magnetic sensor 6. However, a value when the magnetic sensor 6 faces one end of the detection region R1 (the value at the left end in FIG. 6) matches a value when the magnetic sensor 6 faces the other end of the detection region R1 (the value at the right end in FIG. 6).

Thus, in the substantially entire range of movement of the magnetic sensor 6, the processing circuit 21 can uniquely determine, based on the third determination value J3, the position of the magnetic sensor 6. Note that the position-sensing system 1 may include a component that restricts the magnetic sensor 6 from moving to a location where the magnetic sensor 6 faces the one end or the other end of the detection region R1. By restricting the range of movement of the magnetic sensor 6 in this way, the processing circuit 21 can uniquely determine, based on the third determination value J3, the position of the magnetic sensor 6 within the entire range of movement of the magnetic sensor 6. In other words, the processing circuit 21 can determine, as the position of the magnetic sensor 6, a different position for each magnitude of the third determination value J3.

The processing circuit 21 at least stores, in the memory, for example, the relationship between the third determination value J3 and the position of the magnetic sensor 6 in the form of an arithmetic equation or a data table. The processing circuit 21 may refer to the arithmetic equation or the data table, thereby determining the position of the magnetic sensor 6 from the third determination value J3. That is, the third determination value J3 represented on the ordinate in the lower section in FIG. 6 is at least converted into the coordinate (the position of the magnetic sensor 6) represented on the abscissa.

As described above, the processing circuit 21 determines, based on information on the phase of the output (the first voltage Vo1 and the second voltage Vo2) of the first sensor part 61 and the phase of the output (the first voltage Vo3 and the second voltage Vo4) of the second sensor part 62, the position of the magnetic sensor 6 relative to the magnet member 3. That is, the process of converting the first voltage Vo1 and the second voltage Vo2 into the first determination value J1 makes the first determination value J1 hold the information on the phases of the first voltage Vo1 and the second voltage Vo2. In other words, the first determination value J1 includes the information on the phases of the first voltage Vo1 and the second voltage Vo2. Moreover, the process of converting the first voltage Vo3 and the second voltage Vo4 into the second determination value J2 makes the second determination value J2 hold the information on the phases of the first voltage Vo3 and the second voltage Vo4. In other words, the second determination value J2 includes the information on the phases of the first voltage Vo3 and the second voltage Vo4. Furthermore, the process of converting the first determination value J1 and the second determination value J2 into the third determination value J3 makes the third determination value J3 hold the information on the phases of the first voltages Vo1 and Vo3 and the second voltages Vo2 and Vo4. In other words, the third determination value J3 includes the information on the phases of the first voltages Vo1 and Vo3 and the second voltages Vo2 and Vo4. Then, the processing circuit 21 determines, based on the third determination value J3, the position of the magnetic sensor 6 relative to the magnet member 3.

Note that all of the pieces information on the phases of the first voltages Vo1 and Vo3 and the second voltages Vo2 and Vo4 does not have to be held by the first determination value J1, the second determination value J2, or the third determination value J3, but at least some of the pieces of information are at least held by the first determination value J1, the second determination value J2, or the third determination value J3. For example, the first voltage Vo1 and the second voltage Vo2 may be converted into the first determination value J1 having a half cycle of the cycle of each of the first voltage Vo1 and the second voltage Vo2, thereby making the first determination value J1 hold only a half of the pieces of information on the phases.

As described above, as the coordinates of the first sensor part 61 and the second sensor parts 62 in the sensing direction D1 change over the distance between both ends of each magnetic pole (each first magnetic pole 40 and each second magnetic pole 50), the first determination value J1 and the second determination value J2 linearly change. That is, the output of each of the first sensor part 61 and the second sensor part 62 is different for each position between both the ends of the magnetic pole. Moreover, the first magnetic pole number of first magnetic poles 40 and the second magnetic pole number of second magnetic poles 50 are arranged within the detection region R1, and the first magnetic pole number and the second magnetic pole number are coprime. As a result, within a substantially entire region of the detection region R1, a combination of the first determination value J1 and the second determination value J2 obtained from the outputs respectively of the first sensor part 61 and the second sensor part 62 is different from a combination of the first determination value J1 and the second determination value J2 at another position. Thus, within the substantially entire region of the detection region R1, the processing circuit 21 can uniquely determine, based on the first determination value J1 and the second determination value J2, the position of the magnetic sensor 6.

Moreover, as described above, the processing circuit 21 converts the outputs of the first sensor part 61 and the second sensor part 62 into the coordinate (the location) of the magnetic sensor 6. In the conversion process, a process of, for example, binarizing the outputs of the first sensor part 61 and the second sensor part 62 is not performed. Therefore, a slight change in the outputs of the first sensor part 61 and the second sensor part 62 may also change the coordinate (the position) of the magnetic sensor 6 to be determined by the processing circuit 21. More specifically, the position sensing resolution relating to the position of the magnetic sensor 6 results in resolution according to the resolution of the outputs of the first sensor part 61 and the second sensor part 62. Thus, the position detection resolution is suppressed from decreasing below the resolution of the outputs of the first sensor part 61 and the second sensor part 62.

Since the outputs of the first sensor part 61 and the outputs of the second sensor part 62 each have a sinusoidal waveform, the outputs of the first sensor part 61 and the outputs of the second sensor part 62 are easily associated with the position of the magnetic sensor 6. This improves the accuracy of position sensing. The outputs of the first sensor part 61 and the outputs of the second sensor part 62 each preferably have a sinusoidal waveform as accurate as possible.

The position-sensing system 1 preferably further includes an outputter 7 (see FIG. 1). The outputter 7 outputs position information representing the position of the magnetic sensor 6 determined by the processing circuit 21. The outputter 7 may output the position information, for example, to memory provided in the interior or exterior of the position-sensing system 1, thereby storing the position information in the memory. Alternatively, the outputter 7 may output the position information to a presentation unit, such as a display or a loudspeaker, provided in the interior or exterior of the position-sensing system 1, and the presentation unit may present the position information by an image or voice.

(First Variation of First Embodiment)

A position-sensing system 1 according to a first variation of the first embodiment will be described below with reference to FIG. 1. The position-sensing system 1 of the first variation is different from that of the first embodiment in terms of a process performed by the processing circuit 21. Components similar to those in the first embodiment are denoted by the same reference signs as in the first embodiment, and the description thereof will be omitted.

The first sensor part 61 is associated with the first track 4, and the second sensor part 62 is associated with the second track 5. The processing circuit 21 determines the position of the magnetic sensor 6 relative to the magnet member 3 at resolution according to resolution of an output of one of the sensor parts, the one of the sensor parts is associated with one of the first track 4 or the second track 5, and the one of the first track 4 or the second track 5 has a smaller magnet pole pitch than the other of the first track 4 or the second track 5. In the first variation, the magnetic pole pitch P1 of the first magnetic pole number of first magnetic poles 40 of the first track 4 is smaller than the magnetic pole pitch P2 of the second magnetic pole number of second magnetic poles 50 of the second track 5. Thus, the processing circuit 21 determines the position of the magnetic sensor 6 relative to the magnet member 3 at resolution according to the resolution of the output (the first voltage Vo1 and the second voltage Vo2) of the first sensor part 61 associated with the first track 4.

The processing circuit 21 performs, with reference to, for example, a first data table representing the relationship between the first determination value J1 and the position of the magnetic sensor 6, a first process of obtaining one or more options for the position of the magnetic sensor 6. The processing circuit 21 further performs, with reference to a second data table representing the relationship between the second determination value J2 and the position of the magnetic sensor 6, a second process of determining a position corresponding to the second determination value J2 from the one or more options for the position of the magnetic sensor 6. The processing circuit 21 defines the position determined by the second process as a final output representing the position of the magnetic sensor 6. That is, in the first process, the first data table is used to determine the position of the magnetic sensor 6 on the first magnetic pole 40, and in the second process, the second data table is used to determine, from the first magnetic pole number of first magnetic poles 40, a magnetic pole on which the magnetic sensor 6 is disposed. The resolution of the position of the magnetic sensor 6 relative to the magnet member 3 depends on the first process performed based on the output of the first sensor part 61. That is, the resolution of the position of the magnetic sensor 6 relative to the magnet member 3 results in resolution according to the resolution of the output of the first sensor part 61.

In a specific example, as shown in FIG. 3, four corresponding coordinates exist for each one value of the first determination value J1, the first process thus defines the four coordinates as the options for the position of the magnetic sensor 6. Moreover, one coordinate of the four coordinates which corresponds to the second determination value J2 is determined by the second process and is defined as the final output representing the position of the magnetic sensor 6. More specifically, for example, when J1=0 and J2=π, the coordinates corresponding to the first determination value J1 are the coordinates of left ends of the first magnetic poles 41, 42, 43, and 44, and four options thus exist, and of the four options, the coordinate corresponding to the second determination value J2 are only the coordinate of the left end of the first magnetic pole 43. Thus, the processing circuit 21 defines the coordinate of the left end of the first magnetic pole 43 as the final output representing the position of the magnetic sensor 6.

The magnetic pole pitch P1 is smaller than the magnetic pole pitch P2. Thus, as shown in FIGS. 3A and 3B, cycles of the first voltage Vo1 and the second voltage Vo2 of the first sensor part 61 with respect to the change in the position of the magnetic sensor 6 are respectively shorter than cycles of the first voltage Vo3 and the second voltage Vo4 of the second sensor part 62. Moreover, when the position of the magnetic sensor 6 changes by a certain distance, change amounts of the first voltage Vo1 and the second voltage Vo2 of the first sensor part 61 are respectively larger than change amounts of the first voltage Vo3 and the second voltage Vo4 of the second sensor part 62. The processing circuit 21 determines the position of the magnetic sensor 6 relative to the magnet member 3 at the resolution according to the resolution of the output of the first sensor part 61, and therefore, the resolution of the position of the magnetic sensor 6 results in relatively high resolution. That is, the resolution of the position of the magnetic sensor 6 is increased more than in the case where the processing circuit 21 determines the position of the magnetic sensor 6 relative to the magnet member 3 at resolution according to the resolution of the output (the first voltage Vo3 and the second voltage Vo4) of the second sensor part 62.

In the first variation, it has been described that the position of the magnetic sensor 6 is determined based on the data tables, but based on an arithmetic equation, in place of the data tables, the position of the magnetic sensor 6 may be determined.

(Second Variation of First Embodiment)

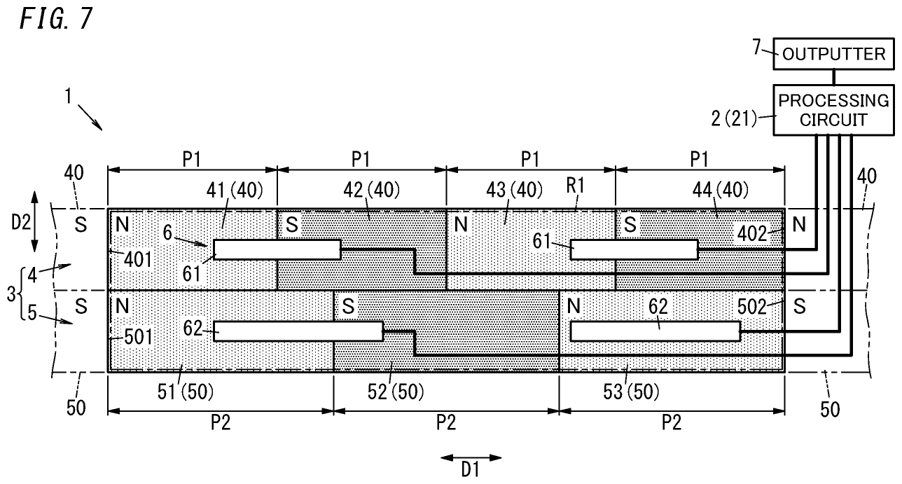

A position-sensing system 1 according to a second variation of the first embodiment will be described below with reference to FIG. 7. Components similar to those in the first embodiment are denoted by the same reference signs as in the first embodiment, and the description thereof will be omitted.

The position-sensing system 1 of the second variation is different from that of the first embodiment in terms of the configuration of the magnetic sensor 6. That is, the magnetic sensor 6 includes a plurality of first sensor parts 61 and a plurality of second sensor parts 62. The plurality of (in FIG. 7, two) first sensor parts 61 are aligned with each other in the sensing direction D1. The plurality of (in FIG. 7, two) second sensor parts 62 are aligned with each other in the sensing direction D1.

The two first sensor parts 61 are disposed to be adjacent to the first track 4. Each of the two first sensor parts 61 senses magnetism produced at the first track 4. The two second sensor parts 62 are disposed to be adjacent to the second track 5. Each of the two second sensor parts 62 senses magnetism produced at the second track 5.

The processing circuit 21 determines, based on outputs of the two first sensor parts 61 and outputs of the two second sensor parts 62, the position of the magnetic sensor 6 with respect to the magnet member 3. The position of the magnetic sensor 6 is at least defined as any one point of the magnetic sensor 6. In this variation, for example, the position of the magnetic sensor 6 is defined as the position of one end (in FIG. 7, left end) of one (in FIG. 7, the first sensor part 61 at the left side) of the two first sensor parts 61 in the sensing direction D1.

The processing circuit 21 obtains a third determination value J3 based on, for example, the output of one first sensor part 61 (the first sensor part 61 at the right side in FIG. 7) and the output of one second sensor part 62 (the second sensor part 62 at the right side in FIG. 7) in a similar manner to the first embodiment. The processing circuit 21 further obtains, in a similar manner, a third determination value J3 based on the output of the other first sensor part 61 (the first sensor part 61 at the left side in FIG. 7) and the output of the other second sensor part 62 (the second sensor part 62 at the left side in FIG. 7). That is, the processing circuit 21 obtains two third determination values J3. The processing circuit 21 then determines, based on the two third determination value J3, the position of the magnetic sensor 6 relative to the magnet member 3. More specifically, the processing circuit 21 determines, for example, based on a combination of the two third determination values J3, and with reference to an arithmetic equation or a data table, the position of the magnetic sensor 6 relative to the magnet member 3.

In the second variation, the accuracy of position sensing is improved more than in the case where the magnetic sensor 6 includes only one first sensor part 61 and only one second sensor part 62.

Moreover, the processing circuit 21 may compare the outputs of the two first sensor parts 61 with each other. Thus, the processing circuit 21 may determine whether or not a failure is in the two first sensor parts 61. The processing circuit 21 obtains, for example, a difference between the output of the one first sensor part 61 when the one first sensor part 61 is at a prescribed location and the output of the other first sensor part 61 when the other first sensor part 61 is at the prescribed location. If the difference is greater than or equal to a prescribed value, the processing circuit 21 determines that a failure is in at least one of the first sensor parts 61. Moreover, the two first sensor parts 61 may be arranged such that the distance between the two first sensor parts 61 corresponds to an integral multiple of the magnetic pole pitch P1. In this case, if the difference between the outputs of the two first sensor parts 61 is greater than or equal to the prescribed value, the processing circuit 21 may determine that a failure is in at least one of the first sensor part 61.

In a similar manner, the processing circuit 21 may compare the outputs of the two second sensor parts 62 with each other. Thus, the processing circuit 21 may determine whether or not a failure is the two second sensor parts 62. Moreover, the two second sensor parts 62 may be arranged such that the distance between the two second sensor parts 62 corresponds to an integral multiple of the magnetic pole pitch P2. In this case, if the difference between the outputs of the two second sensor parts 62 is greater than or equal to the prescribed value, the processing circuit 21 may determine that a failure is in at least one of the second sensor parts 62.

(Third Variation of First Embodiment)

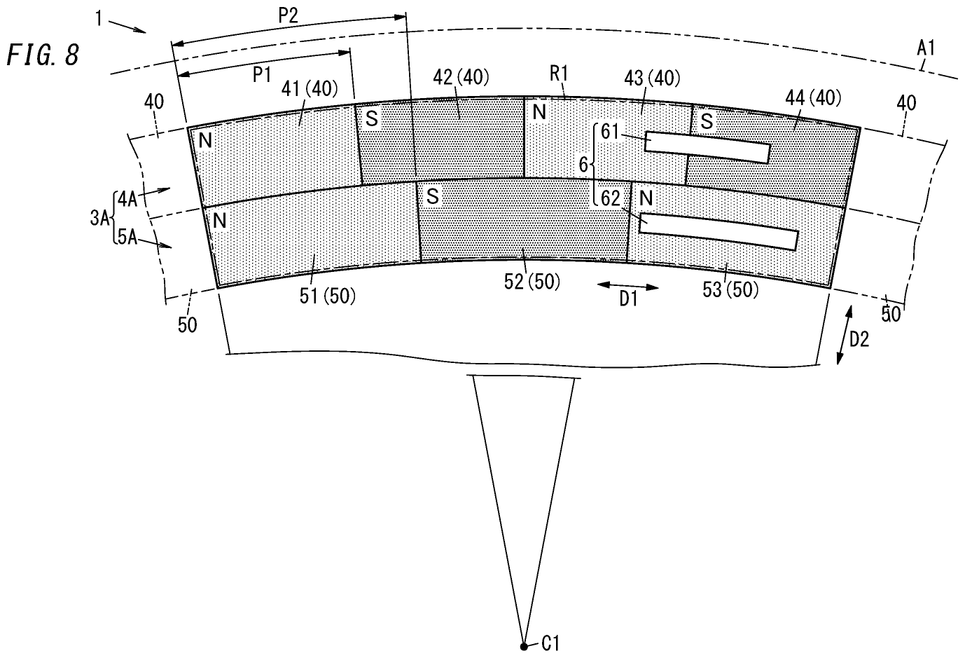

A position-sensing system 1 according to a third variation of the first embodiment will be described below with reference to FIG. 8. Components similar to those in the first embodiment are denoted by the same reference signs as in the first embodiment, and the description thereof will be omitted. Note that in FIG. 8, the processing circuit 21 and the outputter 7 are omitted.

In the position-sensing system 1 of the third variation, the shape of a magnet member 3A is different from the shape of the magnet member 3 of the first embodiment. That is, the magnet member 3A has an arc shape. More specifically, the magnet member 3A has a circular-arc shape. The position-sensing system 1 of the third variation is used as an encoder for sensing the movement of the magnetic sensor 6 along the shape of the magnet member 3A.

The magnet member 3A has a first track 4A and a second track 5A each of which has an arc shape. More specifically, each of the first track 4A and the second track 5A has a circular-arc shape. The first track 4A and the second track 5A are concentrically arranged to be radially adjacent to each other. On a side facing away from a center C1 of the circular arc, the first track 4A is disposed, and on a side facing the center C1 of the circular arc, the second track 5A is disposed. The plurality of first magnetic poles 40 are aligned in the sensing direction D1 along a direction of the circular arc of the magnet member 3A. The plurality of second magnetic poles 50 are aligned in the sensing direction D1.

The magnetic pole pitch P1 of the plurality of first magnetic poles 40 and the magnetic pole pitch P2 of the plurality of second magnetic poles 50 are defined as lengths on an identical circular arc Al around the center C1. That is, in the radial direction (the direction D2) of the magnet member 3A, the first track 4A and the second track 5A are projected onto the circular arc A1. In this case, on the circular arc A1, when the plurality of first magnetic poles 40 are tracked toward one side in the sensing direction D1, the distance from one end, at the one side, of a first magnetic pole 40 to one end of another first magnetic pole 40 adjacent to the first magnetic pole 40 is the magnetic pole pitch P1. The magnetic pole pitch P1 is equal to the length in the sensing direction D1 of each first magnetic pole 40 projected onto the circular arc A1. Moreover, on the circular arc A1, when the plurality of second magnetic poles 50 are tracked toward one side in the sensing direction D1, the distance from one end, at the one side, of a second magnetic pole 50 to one end of another second magnetic pole 50 adjacent to the second magnetic pole 50 is the magnetic pole pitch P2. The magnetic pole pitch P2 is equal to the length in the sensing direction D1 of each second magnetic pole 50 projected onto the circular arc A1.

A detection region R1 is a circular arc-shaped area. The magnet member 3A includes a first magnetic pole number of first magnetic poles 40 and a second magnetic pole number of second magnetic poles 50 within the detection region R1.

The magnetic sensor 6 rotates around the center C1 of the circular arc of the magnet member 3A. Thus, the direction of movement of the magnetic sensor 6 coincides with the sensing direction D1.

In the third variation, the movement of the magnetic sensor 6 relative to the magnet member 3A is a movement along the circular-arc shape of the magnet member 3A. That is, the position-sensing system 1 can sense the movement of the magnetic sensor 6 along the circular-arc shape.

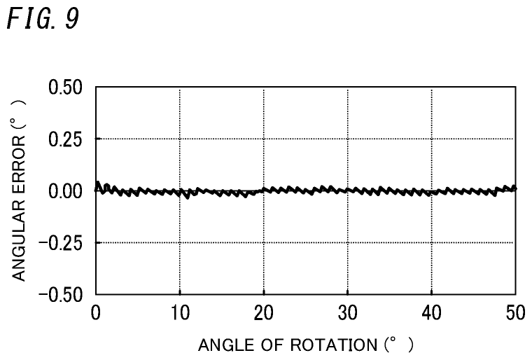

FIG. 9 shows an example of a result of sensing the position of the magnetic sensor 6 relative to the magnet member 3A by the position-sensing system 1 of the third variation. In FIG. 9, the abscissa represents the angle of rotation of the magnetic sensor 6 around the center C1. In FIG. 9, the ordinate represents the magnitude of the error of the result of sensing by the position-sensing system 1 with respect to the value along the abscissa. The magnitude of the error of the result of sensing by the position-sensing system 1 is within a range from −0.1° to +0.1°.

The magnetic sensor 6 may be movable along the sensing direction D1 (circumferential direction) to a location where the magnetic sensor 6 faces part of the magnet member 3A outside the detection region R1. In this case, the processing circuit 21 is configured to sense, based on an output of the first sensor part 61 and an output of the second sensor part 62, the relative position of the magnetic sensor 6. That is, in this case, the position-sensing system 1 is used as an incremental encoder for sensing a relative position.

Note that the magnet member 3A may have an annular shape. The magnet member 3A may have a circularly annular shape.

(Fourth Variation of First Embodiment)

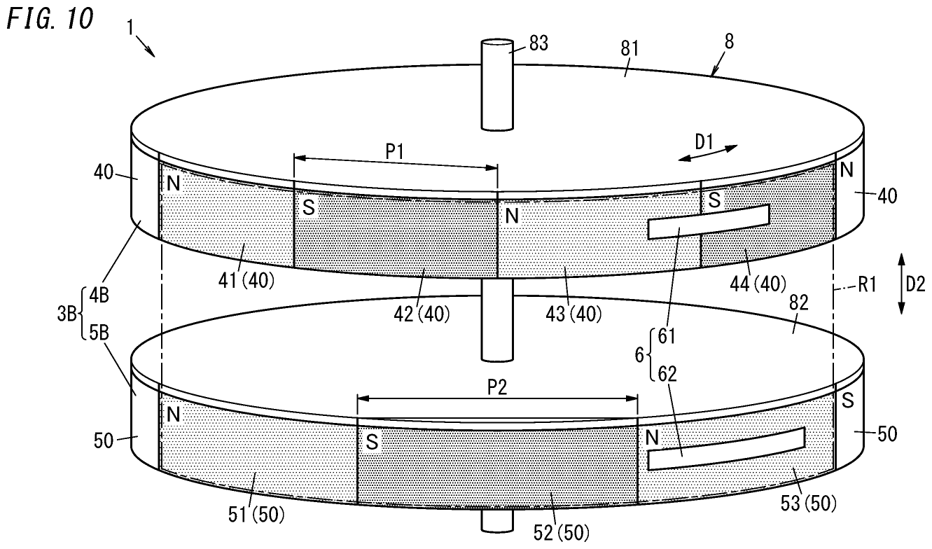

A position-sensing system 1 according to a fourth variation of the first embodiment will be described below with reference to FIG. 10. Components similar to those in the first embodiment are denoted by the same reference signs as in the first embodiment, and the description thereof will be omitted. Note that in FIG. 10, the processing circuit 21 and the outputter 7 are omitted.

In the position-sensing system 1 of the fourth variation, the shape of a magnet member 3B is different from the shape of the magnet member 3 of the first embodiment. That is, the magnet member 3B has an annular shape. More specifically, the magnet member 3B has a circularly annular shape. The position-sensing system 1 of the fourth variation is used as a rotary encoder.

The position-sensing system 1 further includes a holder member 8 for holding the magnet member 3B. The holder member 8 includes a first rotor 81, a second rotor 82, and a shaft 83. The first rotor 81 and the second rotor 82 each have a disk shape. The shaft 83 connects the first rotor 81 to the second rotor 82. The first rotor 81, the second rotor 82, and the shaft 83 together rotate with the shaft 83 being as an axis.

The plurality of first magnetic poles 40 are aligned in the sensing direction D1 which is the same direction as the rotation direction of the holder member 8. The plurality of first magnetic poles 40 are attached to an outer peripheral surface of the first rotor 81.

The plurality of second magnetic poles 50 are aligned in the sensing direction D1. The plurality of second magnetic poles 50 are attached to an outer peripheral surface of the second rotor 82.

The magnet member 3B includes a first magnetic pole number of first magnetic poles 40 and a second magnetic pole number of second magnetic poles 50 within a detection region R1.

The magnetic sensor 6 is held by a member provided as a member separate from the holder member 8. In the present variation, the magnet member 3B of the magnetic sensor 6 and the magnet member 3B moves (rotates). The processing circuit 21 obtains, based on an output of the magnetic sensor 6, the angle of rotation of the magnet member 3B.

As shown in the fourth variation, the position-sensing system 1 may be used as a rotary encoder.

(Other Variations of First Embodiment)

Other variations of the first embodiment will be described below. The variations described below may be accordingly combined with each other. The variations described below may be accordingly combined with the variations described above.

The position-sensing system 1 includes the magnet member 3. The magnet member 3 may alone be distributed to markets independently of the other components of the position-sensing system 1.

Functions similar to those of the position-sensing circuit 2 and the position-sensing system 1 may be implemented as a position-sensing method, a (computer) program, a non-transitory storage medium storing a program, or the like.

A position-sensing method according to an aspect includes a processing step. The processing step includes processing an output of a magnetic sensor 6. The magnetic sensor 6 senses magnetism produced by a magnet member 3. The magnet member 3 includes a first track 4 having a plurality of first magnetic poles 40 and a second track 5 having a plurality of second magnetic poles 50. The plurality of first magnetic poles 40 are magnetic poles exhibiting N polarity and magnetic poles exhibiting S polarity which are alternately aligned in a sensing direction D1 which is prescribed. The plurality of second magnetic poles 50 are magnetic poles exhibiting N polarity and magnetic poles exhibiting S polarity which are alternately aligned in the sensing direction D1. A magnetic pole pitch P1 of the plurality of first magnetic poles 40 in the sensing direction D1 is different from a magnetic pole pitch P2 of the plurality of second magnetic poles 50 in the sensing direction D1. The magnetic sensor 6 includes a first sensor part 61 configured to sense magnetism produced at the first track 4 and a second sensor part 62 configured to sense magnetism produced at the second track 5. At least one of the magnetic sensor 6 or the magnet member 3 moves along the sensing direction D1 relative to the other of the magnetic sensor 6 or the magnet member 3. The processing step includes determining, based on information on a phase of an output of the first sensor part 61 and a phase of an output of the second sensor part 62, a position of the magnetic sensor 6 relative to the magnet member 3.

A program according to an aspect is a program configured to cause one or more processors to execute the position-sensing method.

The position-sensing system 1 according to the present disclosure includes a computer system. The computer system includes a processor and memory as principal hardware components. The functions of the position-sensing system 1 according to the present disclosure may be implemented by making the processor execute a program stored in the memory of the computer system. The program may be stored in the memory of the computer system in advance, may be provided via telecommunications network, or may be provided as a non-transitory recording medium such as a computer system-readable memory card, optical disc, or hard disk drive storing the program. The processor of the computer system may be made up of a single or a plurality of electronic circuits including a semiconductor integrated circuit (IC) or a largescale integrated circuit (LSI). The integrated circuit such as IC or LSI mentioned herein may be referred to in another way, depending on the degree of the integration and includes integrated circuits called system LSI, very-large-scale integration (VLSI), or ultra-large-scale integration (ULSI). Optionally, a field-programmable gate array (FPGA) to be programmed after an LSI has been fabricated or a reconfigurable logic device allowing the connections or circuit sections inside of an LSI to be reconfigured may also be adopted as the processor. The plurality of electronic circuits may be collected on one chip or may be distributed on a plurality of chips. The plurality of chips may be collected in one device or may be distributed in a plurality of devices. As mentioned herein, the computer system includes a microcontroller including one or more processors and one or more memory elements. Thus, the microcontroller is also composed of one or more electronic circuits including a semiconductor integrated circuit or a large-scale integrated circuit.

Moreover, collecting the plurality of functions of the position-sensing system 1 in one housing is not an essential configuration of the position-sensing system 1. The components of the position-sensing system 1 may be distributed in a plurality of housings. Moreover, at least some functions of the position-sensing system 1 may be implemented by cloud (cloud computing) or the like.

In contrast, in the first embodiment, at least some functions of the position-sensing system 1 distributed in a plurality of devices may be collected in one housing.

The magnetic sensor 6 may be movable along the sensing direction D1 to a location where the magnetic sensor 6 faces part of the magnet member 3 outside the detection region RE In this case, the processing circuit 21 is configured to sense, based on the output of the first sensor part 61 and the output of the second sensor part 62, the relative position of the magnetic sensor 6. That is, in this case, the position-sensing system 1 is used as an incremental encoder for sensing a relative position.

Moreover, when the magnetic sensor 6 is at a location where the magnetic sensor 6 faces the part of the magnet member 3 outside the detection region R1, the processing circuit 21 may sense, based on the output of at least one of the first sensor part 61 or the second sensor part 62, the relative position of the magnetic sensor 6. In contrast, when the magnetic sensor 6 is at a location where the magnetic sensor 6 faces the detection region R1 of the magnet member 3, the processing circuit 21 may sense, based on the outputs of both the first sensor part 61 and the second sensor part 62, the absolute position of the magnetic sensor 6.

Obtaining the first determination value J1, the second determination value J2, and the third determination value J3 is not essential, and the processing circuit 21 may directly determine the position of the magnetic sensor 6 from the first voltages Vo1 and Vo3 and the second voltages Vo2 and Vo4. Alternatively, the processing circuit 21 may directly determine the position of the magnetic sensor 6 from the first determination value J1 and the second determination value J2. That is, similarly to that the third determination value J3 is different for each position in a substantially entire range of movement of the magnetic sensor 6, a combination of the first voltages Vo1 and Vo3 and the second voltages Vo2 and Vo4, and also a combination of the first determination value J1 and the second determination value J2 is different for each position. Thus, the processing circuit 21 can uniquely determine the position of the magnetic sensor 6 from the combination of the first voltages Vo1 and Vo3 and the second voltages Vo2 and Vo4 or the combination of the first determination value J1 and the second determination value J2 in a substantially entire (or an entire) range of movement of the magnetic sensor 6.

Alternatively, the processing circuit 21 may determine, based on at least one of the first determination value J1 or the second determination value J2 and the third determination value J3, the position of the magnetic sensor 6.

The magnetic pole pitch P1 may be defined by a length of each of the plurality of first magnetic poles 40 in the sensing direction D1. Alternatively, the magnetic pole pitch P1 may be defined as an average value of lengths of the plurality of first magnetic poles 40 in the sensing direction D1.

The magnetic pole pitch P2 may be defined as a length of each of the plurality of second magnetic poles 50 in the sensing direction D1. Alternatively, the magnetic pole pitch P2 may be defined as an average value of lengths of the plurality of second magnetic poles 50 in the sensing direction D1.

It is not essential that the first magnetic pole number and the second magnetic pole number are numbers close to each other.

The magnetic sensor 6 is not limited to a sensor including the artificial lattice-type GMR element 63. The magnetic sensor 6 may be, for example, a Semiconductor Magneto Resistive (SMR) element or an Anisotropic Magneto Resistive (AMR) element.

The substrate 630 of the GMR element 63 is not limited to the silicon substrate. The substrate 630 may be, for example, a glass glaze substrate obtained by glazing an alumina substrate with glass.

### Second Embodiment

(1) Overview

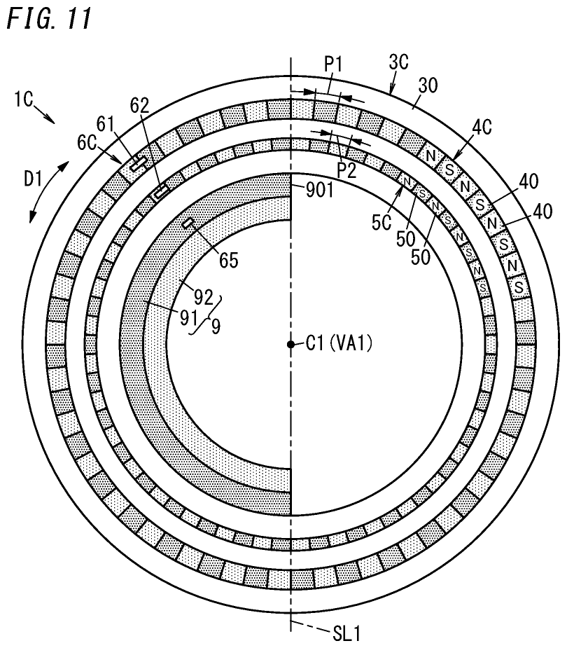

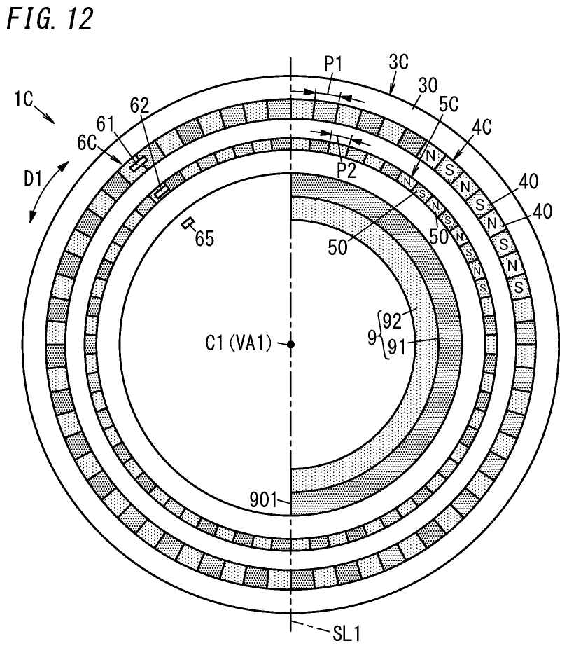

A position-sensing system 1C according to a second embodiment will be described below with reference to FIGS. 11 to 13C. Components similar to those in the first embodiment are denoted by the same reference signs as in the first embodiment, and the description thereof will be omitted. Note that in FIGS. 11 and 12, a processing circuit 21 and an outputter 7 are omitted.

The position-sensing system 1C of the present embodiment is used as a rotary encoder for sensing a rotation movement of a magnet member 3C or a magnetic sensor 6C. More specifically, the position-sensing system 1C is used as an absolute rotary encoder. That is, the position-sensing system 1C senses an absolute angle of rotation of the magnetic sensor 6C relative to the magnet member 3C.

At least one of the magnetic sensor 6C or the magnet member 3C rotationally moves relative to the other of the magnetic sensor 6C or the magnet member 3C. More specifically, at least one of the magnetic sensor 6C or the magnet member 3C rotates relative to the other of the magnetic sensor 6C or the magnet member 3C by 360 degrees. In the present embodiment, the magnet member 3C of the magnet member 3C and the magnetic sensor 6C rotationally moves. FIG. 12 shows the magnet member 3C after rotation from the state shown in FIG. 11 by 180 degrees. The rotation movement is a movement along a sensing direction D1 which is a direction of rotation around a virtual axis VA1. More specifically, the rotation movement is a rotation movement with the virtual axis VA1 serving as a rotation axis.

The magnet member 3C rotates relative to the magnetic sensor 6C by 360 degrees, and thus, a range (detection region) of the magnet member 3C which is to face the magnetic sensor 6C is a range that circles the magnet member 3C.

(2) Magnet Member

The magnet member 3C has a first track 4C and a second track 5C each formed by printing magnetic ink onto a base material 30 in the form of a sheet. A thickness direction defined with respect to the base material 30 is along the length direction of the virtual axis VA1 (a depth direction with respect to the plane of FIG. 11). When viewed in the length direction of the virtual axis VA1, the base material 30, the first track 4C, and the second track 5C each have an annular shape. More specifically, the base material 30, the first track 4C, and the second track 5C each have a circularly annular shape.

The base material 30, the first track 4C, and the second track 5C encircle the virtual axis VA1, which is common to the base material 30, the first track 4C, and the second track 5C. Centers C1 of the base material 30, the first track 4C, and the second track 5C coincide with each other. The virtual axis VA1 extends through the centers C1.

A plurality of first magnetic poles 40 are magnetic poles exhibiting N polarity and magnetic poles exhibiting S polarity which are alternately aligned in a sensing direction D1 (rotation direction). A plurality of second magnetic poles 50 are magnetic poles exhibiting N polarity and magnetic poles exhibiting S polarity which are alternately aligned in the sensing direction D1. In FIG. 11, some of the magnetic poles exhibiting N polarity are denoted by the alphabet “N”, and some of the magnetic poles exhibiting S polarity are denoted by the alphabet “S”. Moreover, the magnetic poles exhibiting the N polarity are distinguished from the magnetic poles exhibiting S polarity based on the density of shading.

The first magnetic poles 40 are equal to each other in length in the sensing direction D1. The second magnetic poles 50 are equal to each other in length in the sensing direction D1. In the sensing direction D1, the length of each of the plurality of first magnetic poles 40 (a magnetic pole pitch P1) is longer than the length of each of the plurality of second magnetic poles 50 (a magnetic pole pitch P2). The magnetic pole pitches P1 and P2 are specified in a similar manner to the third variation of the first embodiment, and the description thereof is thus omitted.

The number of first magnetic poles 40 and the number of second magnetic poles 50 are even numbers. In FIG. 11, a straight line SL1 is a straight line bisecting the magnet member 3C. Moreover, the difference between the number of first magnetic poles 40 and the number of second magnetic poles 50 is two. Thus, magnet member 3C has a two-fold symmetric shape. In FIG. 11, the number of first magnetic poles 40 is 64, and the number of second magnetic poles 50 is 66.

The magnet member 3C includes a third track 9 in addition to the first track 4C and the second track 5C. The third track 9 includes two third magnetic poles 91 and 92. The third magnetic pole 91 is a magnetic pole exhibiting S polarity, and the third magnetic pole 92 is a magnetic pole exhibiting N polarity. That is, the number of pairs of poles of the third track 9 is one.

When viewed in the length direction of the virtual axis VA1, each of the two third magnetic poles 91 and 92 has a semi-annular shape. More specifically, each of the two third magnetic poles 91 and 92 has a semicircularly annular shape. Each of the two third magnetic poles 91 and 92 is disposed to correspond to a semi-circumference of a circle around the virtual axis VA1. Centers C1 of the two third magnetic poles 91 and 92, the base material 30, the first track 4C, and the second track 5C coincide with one other.

When viewed in the length direction of the virtual axis VA1, the third magnetic pole 91 is disposed on an outer side of the third magnetic pole 92. However, when viewed in the length direction of the virtual axis VA1, the third magnetic pole 91 may be disposed on an inner side of the third magnetic pole 92.

The third track 9 is fixed to the base material 30. Thus, the third track 9, the first track 4C, and the second track 5C are together rotatable in the sensing direction D1.

When viewed in the length direction of the virtual axis VA1, the third track 9 is disposed on an inner side of the base material 30, the first track 4C, and the second track 5C. However, the arrangement of the third track 9 is not limited to this example. The third track 9 may be disposed on an outer side of the base material 30, the first track 4C, and the second track 5C or may be disposed between the first track 4C and the second track 5C. Moreover, the third track 9 may be disposed on a surface of the base material 30.

(3) Magnetic Sensor

The arrangement of a first sensor part 61 and a second sensor part 62 is similar to that in the third variation (see FIG. 8) of the first embodiment, and thus, the description thereof is omitted.

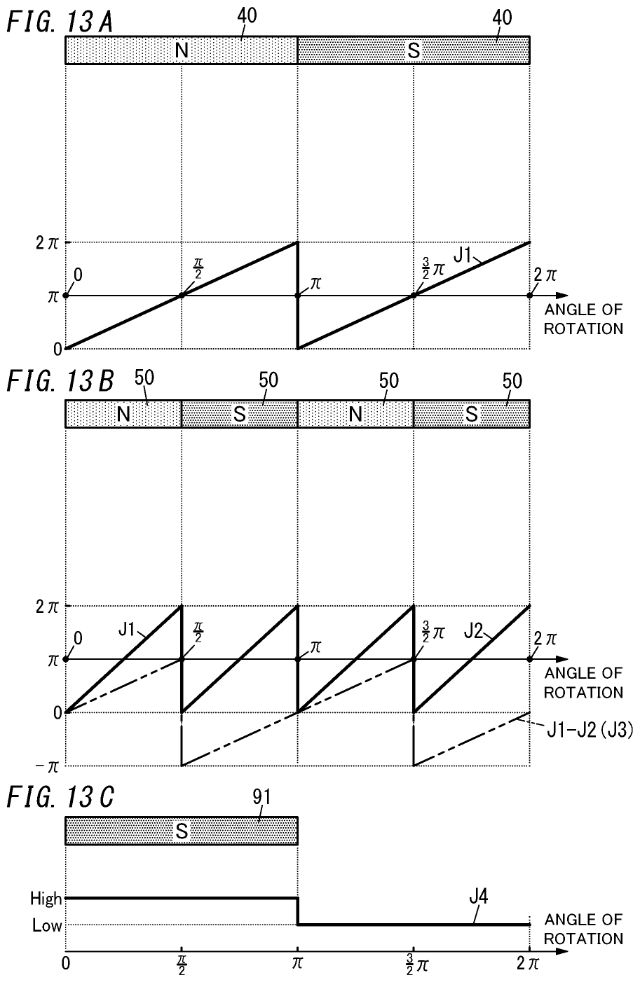

The magnetic sensor 6C includes a determination sensor 65 in addition to the first sensor part 61 and the second sensor part 62. That is, the position-sensing system 1C includes the determination sensor 65. The determination sensor 65 has a function as a magnetic sensor (a function of sensing magnetism). The determination sensor 65 generates and outputs determination information (an output J4: see FIG. 13C) relating to determination of whether or not an absolute angle of rotation of the rotation movement of the magnet member 3C (or the magnetic sensor 6C) is within a range from 0 to π (greater than or equal to 0 and less than π). The position at which the absolute angle of rotation is 0 may be arbitrarily defined. In the present embodiment, an angle of rotation when the determination sensor 65 is located at one end 901 of the third track 9 is defined as 0.

The determination sensor 65, the first sensor part 61, and the second sensor part 62 are aligned with each other in the radial direction of the magnet member 3C. The positional relationship among the determination sensor 65, the first sensor part 61, and the second sensor part 62 is fixed. The determination sensor 65, the first sensor part 61, and the second sensor part 62 are housed in an identical package. The determination sensor 65 includes, for example, at least one artificial lattice-type GMR element. The structure of the GMR element of the determination sensor 65 may be similar to the structure of, for example, the GMR elements 63 (see FIG. 4) of the first sensor part 61 and the second sensor part 62.

The determination sensor 65 senses magnetism produced at the third track 9. When the absolute angle of rotation of the rotation movement of the magnet member 3C including the third track 9 is greater than or equal to 0 and less than π, the determination sensor 65 is located on a surface of the third magnetic pole 91 (see FIG. 11). In other cases (cases where the absolute angle of rotation is greater than or equal to π and less than 2π), the determination sensor 65 is located separately from the third magnetic pole 91 (see FIG. 12). More specifically, when the absolute angle of rotation is greater than or equal to n and less than 2π, no magnetic field is applied to the determination sensor 65 from the magnet member 3C.

Thus, when the absolute angle of rotation is greater than or equal to 0 and less than π, the determination sensor 65 performs a first output, and when the absolute angle of rotation is greater than or equal to π and less than 2π, the determination sensor 65 performs a second output. The first output is an output corresponding to the magnetic field applied from the third magnetic pole 91. The second output is an output corresponding to a non-magnetic field. The second output is an output different from the first output. For example, the first output is a voltage having an absolute value greater than or equal to a prescribed value, and the second output is a voltage having an absolute value less than the prescribed value. FIG. 13C shows the output J4 of the determination sensor 65 when the first output is converted into a High signal and the second output is converted into a Low signal.

(4) Processing Circuit

The processing circuit 21 obtains a first determination value J1 and a second determination value J2 by a process similar to that in the first embodiment. To simplify the explanation, it is assumed in the following description that the number of first magnetic poles 40 is four, and the number of second magnetic poles 50 is two. The first determination value J1 and the second determination value J2 in this case are shown respectively in FIGS. 13A and 13B.

In FIGS. 13A and 13B, the abscissas represent the absolute angle of rotation of the magnet member 3C, and the ordinates respectively represent the first determination value J1 and the second determination value J2. The first determination value J1 and the second determination value J2 change in the shape of a sawtooth wave.

As shown in FIG. 13A, the first determination value J1 linearly increases from 0 to 2π when the absolute angle of rotation of the magnet member 3C increases from 0 to π, and when the absolute angle of rotation of the magnet member 3C increases from π to 2π.

As shown in FIG. 13B, the second determination value J2 linearly increases from 0 to 2π when the absolute angle of rotation of the magnet member 3C increases from 0 to π/2, when the absolute angle of rotation of the magnet member 3C increases from π/2 to π, when the absolute angle of rotation of the magnet member 3C increases from π to 3π/2, and when the absolute angle of rotation of the magnet member 3C increases from 3π/2 to 2π.

The processing circuit 21 obtains a value, as a third determination value J3, by subtracting the second determination value J2 from the first determination value J1. As shown in FIG. 13B, the third determination value J3 linearly increases from −π to π when the absolute angle of rotation of the magnet member 3C increases from π/2 to 3π/2 and when the absolute angle of rotation of the magnet member 3C increases from 3π/2 to 2π(=0) and then increases to π/2. Since the magnet member 3C has a two-fold symmetric shape, each time the absolute angle of rotation of the magnet member 3C changes by π, the third determination value J3 repeatedly forms the same waveform.

In FIG. 13C, the abscissa represents the absolute angle of rotation of the magnet member 3C, and the ordinate represents the output J4 of the determination sensor 65. As described above, when the absolute angle of rotation of the magnet member 3C is greater than or equal to 0 and less than π, the determination sensor 65 performs the first output (the High signal), and when the absolute angle of rotation is greater than or equal to π and less than 2π, the determination sensor 65 performs the second output (the Low signal).

The processing circuit 21 is configured to obtain, based on the output J4 of the determination sensor 65 and information on a phase of an output of the first sensor part 61 and a phase of an output of the second sensor part 62, the absolute angle of rotation of the magnetic sensor 6C relative to the magnet member 3C. In the present embodiment, the information on the phase of the output of the first sensor part 61 and the phase of the output of the second sensor part 62 is the third determination value J3. As shown in FIG. 13B, within a range from 0 to π of the absolute angle of rotation of the magnet member 3C, the third determination value J3 corresponds to the absolute angle of rotation of the magnet member 3C on a one-to-one basis (however, except for points at which the angle of rotation is 0, π/2, and π). Moreover, the waveform of the third determination value J3 within a range within which the absolute angle of rotation of the magnet member 3C is from 0 to π is the same as the waveform of the third determination value J3 within a range within which the absolute angle of rotation of the magnet member 3C is from π to 2π. Thus, the absolute angle of rotation of the magnetic sensor 6C relative to the magnet member 3C is obtainable based on the output J4 of the determination sensor 65 and the third determination value J3. Specifically, the processing circuit 21 obtains an absolute angle θ1 of rotation of the magnetic sensor 6C relative to the magnet member 3C using (Formula 5) indicated below.

θ1=J3/2 (0≤J3≤π, J4=High)

θ1=π−|J3/2|(−π≤J3<0, J4=High)

θ1=π+J3/2 (0≤J3≤π, J4=Low)

θ1=2π−|J3/2|(−π≤J3<0, J4=Low) (Formula 5)

(5) Brief Summary

As described above, the position-sensing system 1C of the present embodiment can obtain the absolute angle of rotation of the magnetic sensor 6C relative to the magnet member 3C over a range from 0 to 2π.

(First Variation of Second Embodiment)

The determination sensor 65 is not limited to the magnetic sensor. When the determination sensor 65 is not a magnetic sensor, the third track 9 may be omitted.

The determination sensor 65 may be, for example, an optical sensor. The optical sensor includes, for example, a light projecting unit and a light receiving unit. In one of the cases where the absolute angle of rotation of the rotation movement of the magnet member 3C is within a range of greater than or equal to 0 and less than π or where the absolute angle of rotation of the rotation movement of the magnet member 3C is outside the range specified above, light projected from a light projecting unit is received by the light receiving unit, and accordingly, the optical sensor performs the first output. In the other of the cases, the light projected from light projecting unit is blocked by an object (e.g., the magnet member 3C), which reduces the quantity of light received by the light receiving unit, and accordingly, the optical sensor performs the second output.

Alternatively, the determination sensor 65 may be a contact-type position sensor. The contact-type position sensor includes a brush. In one of the cases where the absolute angle of rotation of the rotation movement of the magnet member 3C is within a range of greater than or equal to 0 and less than π or where the absolute angle of rotation of the rotation movement of the magnet member 3C is outside the range specified above, the brush comes into contact with a conductor, and accordingly, the contact-type position sensor performs the first output. In the other of the cases, the brush is separated from the conductor, and accordingly, the contact-type position sensor performs the second output.

Alternatively, the determination sensor 65 may be an electrostatic capacity sensor. The electrostatic capacity sensor includes two conductors. The electrostatic capacity between the two conductors differs between the cases where the absolute angle of rotation of the rotation movement of the magnet member 3C is within a range of greater than or equal to 0 and less than π and where the absolute angle of rotation of the rotation movement of the magnet member 3C is outside the range specified above, and the electrostatic capacity sensor performs an output according to the electrostatic capacity between the two conductors. More specifically, in one of the cases where the absolute angle of rotation of the rotation movement of the magnet member 3C is within a range of greater than or equal to 0 and less than π or where the absolute angle of rotation of the rotation movement of the magnet member 3C is outside the range specified above, the electrostatic capacity sensor performs the first output, and in the other of the cases, the electrostatic capacity sensor performs the second output.

(Second Variation of Second Embodiment)

The difference between the first magnetic pole number and the second magnetic pole number is not limited to two. When the difference is 2N (where N is a natural number greater than or equal to two), the third determination value J3 repeatedly forms the same waveform each time the absolute angle of rotation of the magnet member 3C changes by (2π/2N). Thus, the output J4 of the determination sensor 65 at least switches, for example, each time the absolute angle of rotation of the magnet member 3C changes by (2π/2N). The output J4 of the determination sensor 65 is at least converted into a 2N-ary value. The output J4 in this case is an output based on which whether the absolute angle of rotation of the magnet member 3C relative to the magnetic sensor 6C is within a first range (in this variation, from 0 to 2π/2N), within a second range (in this variation, from 2π/2N to 4π/2N), within a third range (in this variation, from 4π/2N to 6π/2N), or . . . is distinguishable. Also in this case, the processing circuit 21 can obtain, based on the output J4 of the determination sensor 65 and the third determination value J3, the absolute angle of rotation of the magnet member 3C.

(Other Variations of Second Embodiment)

Other variations of the second embodiment will be described below. The variations described below may be accordingly combined with each other. The variations described below may be accordingly combined with the above-described variations of the second embodiment.

Each variation of the first embodiment may accordingly be applied to the second embodiment.

The position of the first track 4C and the position of the second track 5C may be different from each other in the length direction of the virtual axis VA1. For example, the first track 4C and the second track 5C may be arranged in a similar manner to those in the fourth variation (see FIG. 10) of the first embodiment. In this case, the third track 9 may be attached to the shaft 83, and the first track 4C, the second track 5C, and the third track 9 may together rotate around the shaft 83 as an axis.

In the present embodiment, description is given provided that “from 0 to π” means “greater than or equal to 0 and less than π”, but “greater than or equal to” may be replaced with “greater than”. Therefore, there is no technical difference between “greater than or equal to” and “greater than”. Similarly, “less than” may be replaced with “less than or equal to”.

When in the present embodiment, the absolute angle of rotation of the rotation movement of the magnet member 3C is greater than or equal to 0 and less than π, the determination sensor 65 is located on a surface of the third magnetic pole 91 (see FIG. 11). However, when the absolute angle of rotation of the rotation movement of the magnet member 3C is greater than or equal to 0 and less than π, the determination sensor 65 may be located on a surface of the third magnetic pole 92.

(Summary)

The embodiments and the like described above disclose the following aspects.

A position-sensing circuit (2) of a first aspect includes a processing circuit (21). The processing circuit (21) is configured to process an output of a magnetic sensor (6, 6C). The magnetic sensor (6, 6C) is configured to sense magnetism produced by a magnet member (3, 3A, 3B, 3C). The magnet member (3, 3A, 3B, 3C) includes a first track (4, 4A, 4B, 4C) having a plurality of first magnetic poles (40) and a second track (5, 5A, 5B, 5C) having a plurality of second magnetic poles (50). The plurality of first magnetic poles (40) are magnetic poles exhibiting N polarity and magnetic poles exhibiting S polarity which are alternately aligned in a sensing direction (D1) which is prescribed. The plurality of second magnetic poles (50) are magnetic poles exhibiting N polarity and magnetic poles exhibiting S polarity which are alternately aligned in the sensing direction (D1). A magnetic pole pitch (P1) between the plurality of first magnetic poles (40) in the sensing direction (D1) is different from a magnetic pole pitch (P2) between the plurality of second magnetic poles (50) in the sensing direction (D1). The magnetic sensor (6, 6C) includes a first sensor part (61) configured to sense magnetism produced at the first track (4, 4A, 4B, 4C) and a second sensor part (62) configured to sense magnetism produced at the second track (5, 5A, 5B, 5C). At least one of the magnetic sensor (6, 6C) or the magnet member (3, 3A, 3B, 3C) is configured to move along the sensing direction (D1) relative to the other of the magnetic sensor (6, 6C) or the magnet member (3, 3A, 3B, 3C). The processing circuit (21) is configured to determine, based on information on a phase of an output of the first sensor part (61) and a phase of an output of the second sensor part (62), a position of the magnetic sensor (6, 6C) relative to the magnet member (3, 3A, 3B, 3C).

In this configuration, the position sensing resolution is improved more than in the case where the processing circuit (21) performs position sensing without referring to the information on the phase of the output of the first sensor part (61) and the phase of the output of the second sensor part (62).

In a position-sensing circuit (2) of a second aspect referring to the first aspect, the magnet member (3, 3A, 3B) has a detection region (R1) which is to face the magnetic sensor (6). The plurality of first magnetic poles (40) include a first magnetic pole number of magnetic poles disposed in the detection region (R1), the plurality of second magnetic poles (50) include a second magnetic pole number of magnetic poles disposed in the detection region (R1), and the first magnetic pole number and the second magnetic pole number are coprime.

In this configuration, the absolute position of the magnetic sensor (6) can be sensed within a wider range than in the case where the first magnetic pole number and the second magnetic pole number are not coprime.

In a position-sensing circuit (2) of a third aspect referring to the second aspect, a difference between the first magnetic pole number and the second magnetic pole number is less than a smaller one of the first magnetic pole number and the second magnetic pole number.

This configuration enables the influence of the second magnetic pole (50) over magnetism around the first magnetic pole (40) to be reduced. This configuration also enables the influence of the first magnetic pole (40) over magnetism around the second magnetic pole (50) to be reduced. This improves the accuracy of position sensing.

In a position-sensing circuit (2) of a fourth aspect referring to any one of the first to third aspects, the processing circuit (21) is configured to determine, based on a value (a third determination value (J3)) corresponding to a difference between a first determination value (J1) based on the output of the first sensor part (61) and a second determination value (J2) based on the output of the second sensor part (62), the position of the magnetic sensor (6, 6C) relative to the magnet member (3, 3A, 3B, 3C).

This configuration enables the processing circuit (21) to determine the position of the magnetic sensor (6, 6C) by a simple process.

In a position-sensing circuit (2) of a fifth aspect referring to any one of the first to fourth aspects, the first sensor part (61) is associated with the first track (4, 4A, 4B, 4C), and the second sensor part (62) is associated with the second track (5, 5A, 5B, 5C). The processing circuit (21) is configured to determine the position of the magnetic sensor (6, 6C) relative to the magnet member (3, 3A, 3B, 3C) at resolution according to resolution of the output of one of the first sensor part (61) or the second sensor part (62). The one of the first sensor part (61) or the second sensor part (62) is associated with one of the first track (4, 4A, 4B, 4C) or the second track (5, 5A, 5B, 5C). The one of the first track (4, 4A, 4B, 4C) or the second track (5, 5A, 5B, 5C) has a smaller magnet pole pitch than the other of the first track (4, 4A, 4B, 4C) or the second track (5, 5A, 5B, 5C).

This configuration enables the resolution to be improved more than in the case of adopting resolution according to resolution of an output of one of the sensor parts, the one of the sensor parts being associated with one of the tracks, the one of the tracks having a smaller magnet pole pitch than the other of the tracks. That is, the position sensing resolution is further improved.

In a position-sensing circuit (2) of a sixth aspect referring to any one of the first to fifth aspects, the first sensor part (61) and the second sensor part (62) each output a signal which is sinusoidal in an orthogonal coordinate system. The orthogonal coordinate system has a coordinate axis representing coordinates of the first sensor part (61) and the second sensor part (62) in the sensing direction (D1) and a coordinate axis representing the outputs of the first sensor part (61) and the second sensor part (62). The coordinate axis representing the coordinates of the first sensor part (61) and the second sensor part (62) is orthogonal to the coordinate axis representing the outputs of the first sensor part (61) and the second sensor part (62).

With this configuration, the output of the first sensor part (61) and the output of the second sensor part (62) are easily associated with the position of the magnetic sensor (6, 6C). This improves the accuracy of position sensing.

In a position-sensing circuit (2) of a seventh aspect referring to any one of the first to sixth aspects, the first track(4C) and the second track (5C) each have an annular shape encircling a virtual axis (VA1) which is common to the first track (4C) and the second track (5C). At least one of the magnetic sensor (6C) or the magnet member (3C) is configured to rotationally move along the sensing direction (D1) relative to the other of the magnetic sensor (6C) or the magnet member (3C). The sensing direction (D1) is a direction of rotation around the virtual axis (VA1). A determination sensor (65) is configured to generate determination information (an output J4). The determination information is information based on which whether or not an absolute angle of rotation of the rotation movement is within a range from 0 to π is determined. The processing circuit (21) is configured to obtain, based on the determination information output from the determination sensor (65) and information on a phase of the output of the first sensor part (61) and a phase of the output of the second sensor part (62), the absolute angle of rotation of the magnetic sensor (6C) relative to the magnet member (3C).

With this configuration, the absolute angle of rotation of the magnetic sensor (6C) relative to the magnet member (3C) is obtainable over a range from 0 to 2π.

The configurations except for the first aspect are not configurations essential for the position-sensing circuit (2) and may thus be accordingly omitted.

A position-sensing system (1, 1C) of an eighth aspect includes the position-sensing circuit (2) of any one of the first to sixth aspect, the magnet member (3, 3A, 3B, 3C), and the magnetic sensor (6, 6C).

This configuration provides improved position sensing resolution.

A position-sensing system (1C) of a ninth aspect includes the position-sensing circuit (2) of the seventh aspect, the magnet member (3C), the magnetic sensor (6C), and the determination sensor (65). The determination sensor (65) is configured to perform a first output when the absolute angle of rotation of the rotation movement is within the range from 0 to π and otherwise perform a second output different from the first output.

With this configuration, the absolute angle of rotation of the magnetic sensor (6C) relative to the magnet member (3C) is obtainable over a range from 0 to 2π.

In a position-sensing system (1C) of a tenth aspect referring to the ninth aspect, the magnet member (3C) includes a third track (9). The third track (9) has a third magnetic pole (91, 92). The magnetic sensor (6C) includes the determination sensor (65). The determination sensor (65) is configured to sense magnetism produced at the third track (9).

With this configuration, the magnetic sensor (6C) has functions of the determination sensor (65), the first sensor part (61), and the second sensor part (62).

In a position-sensing system (1C) of an eleventh aspect referring to the ninth or tenth aspect, a difference between a number of first magnetic poles (40) and a number of second magnetic poles (50) is two.

With this configuration, a cycle of a combination signal (a third determination value J3) of the output of the first sensor part (61) and the output of the second sensor part (62) is longer than in the case where the difference is greater than two.

In a position-sensing system (1) of a twelfth aspect referring to the eighth aspect, the magnet member (3) has a linear shape.

With this configuration, the position-sensing system (1) is usable as a linear encoder.

In a position-sensing system (1, 1C) of a thirteenth aspect referring to the eighth aspect, the magnet member (3A, 3B, 3C) has an arc shape or annular shape.

With this configuration, the position-sensing system (1, 1C) can sense the rotation movement.

In a position-sensing system (1, 1C) of a fourteenth aspect referring to any one of the eighth to thirteenth aspects, the magnetic sensor (6, 6C) includes a plurality of the first sensor parts (61) and a plurality of the second sensor parts (62). The plurality of first sensor parts (61) are aligned with each other in the sensing direction (D1). The plurality of second sensor parts (62) are aligned with each other in the sensing direction (D1).

With this configuration, the accuracy of position sensing is improved more than in the case where the magnetic sensor (6, 6C) includes only one first sensor part (61) and only one second sensor part (62).

In a position-sensing system (1, 1C) of a fifteenth aspect referring to any one of the eighth to fourteenth aspects, the first sensor part (61) and the second sensor part (62) each include an artificial lattice-type GMR element (63).

With this configuration, the accuracy of position sensing is improved because the output waveform is relatively stable in the case of the GMR element (63).

In a position-sensing system (1, 1C) of a sixteenth aspect referring to the fifteenth aspect, the GMR element (63) has a layered structure (640) including cobalt and iron.

This configuration enables the output of the GMR element (63) to be made relatively large.

The configurations except for the eighth aspect are not configurations essential for the position-sensing system (1, 1C) and may thus accordingly be omitted.

A magnet member (3, 3A, 3B, 3C) of a seventeenth aspect is included in the position-sensing system (1, 1C) of any one of the eighth to sixteenth aspects.

This configuration provides improved position sensing resolution.

A position-sensing method of an eighteenth aspect includes a processing step. The processing step includes processing an output of a magnetic sensor (6, 6C). The magnetic sensor (6, 6C) is configured to sense magnetism produced by a magnet member (3, 3A, 3B, 3C). The magnet member (3, 3A, 3B, 3C) includes a first track (4, 4A, 4B, 4C) having a plurality of first magnetic poles (40) and a second track (5, 5A, 5B, 5C) having a plurality of second magnetic poles (50). The plurality of first magnetic poles (40) are magnetic poles exhibiting N polarity and magnetic poles exhibiting S polarity which are alternately aligned in a sensing direction (D1) which is prescribed. The plurality of second magnetic poles (50) are magnetic poles exhibiting N polarity and magnetic poles exhibiting S polarity which are alternately aligned in the sensing direction (D1). A magnetic pole pitch (P1) between the plurality of first magnetic poles (40) in the sensing direction (D1) is different from a magnetic pole pitch (P2) between the plurality of second magnetic poles (50) in the sensing direction (D1). The magnetic sensor (6, 6C) includes a first sensor part (61) configured to sense magnetism produced at the first track (4, 4A, 4B, 4C) and a second sensor part (62) configured to sense magnetism produced at the second track (5, 5A, 5B, 5C). At least one of the magnetic sensor (6, 6C) or the magnet member (3, 3A, 3B, 3C) is configured to move along the sensing direction (D1) relative to the other of the magnetic sensor (6, 6C) or the magnet member (3, 3A, 3B, 3C). The processing step includes determining, based on information on a phase of an output of the first sensor part (61) and a phase of an output of the second sensor part (62), a position of the magnetic sensor (6, 6C) relative to the magnet member (3, 3A, 3B, 3C).

This configuration provides improved position sensing resolution.

A program of a nineteenth aspect is a program configured to cause one or more processors to execute the position-sensing method of the eighteenth aspect.

This configuration provides improved position sensing resolution.

The aspects described above are not to limit the disclosure, but various configurations (including variations) of the position-sensing circuit (2) and the position-sensing system (1, 1C) according to the embodiments can be embodied as a position-sensing method or a program.

### REFERENCE SIGNS LIST

1, 1C Position-Sensing System

2 Position-Sensing Circuit

21 Processing Circuit

3, 3A, 3B, 3C Magnet Member

4, 4A, 4B, 4C First Track

40 First Magnetic Pole

5, 5A, 5B, 5C Second Track

50 Second Magnetic Pole

6, 6C Magnetic Sensor

61 First sensor part

62 Second sensor part

63 GMR Element

640 Layered Structure

65 Determination Sensor

9 Third Track

91, 92 Third Magnetic Pole

D1 Sensing direction

J1 First Determination Value

J2 Second Determination Value

J4 Output (Determination Information)

P1 Magnetic Pole Pitch

P2 Magnetic Pole Pitch

R1 Detection Region

VA1 Virtual Axis

1. A position-sensing circuit comprising:
a processing circuit configured to process an output of a magnetic sensor, the magnetic sensor being configured to sense magnetism produced by a magnet member, the magnet member including a first track having a plurality of first magnetic poles and a second track having a plurality of second magnetic poles,
the plurality of first magnetic poles being magnetic poles exhibiting N polarity and magnetic poles exhibiting S polarity which are alternately aligned in a sensing direction which is prescribed, the plurality of second magnetic poles being magnetic poles exhibiting N polarity and magnetic poles exhibiting S polarity which are alternately aligned in the sensing direction,
a magnetic pole pitch of the plurality of first magnetic poles in the sensing direction being different from a magnetic pole pitch of the plurality of second magnetic poles in the sensing direction,
the magnetic sensor including a first sensor part configured to sense magnetism produced at the first track and a second sensor part configured to sense magnetism produced at the second track,
at least one of the magnetic sensor or the magnet member being configured to move along the sensing direction relative to the other of the magnetic sensor or the magnet member,
the processing circuit being configured to determine, based on information on a phase of an output of the first sensor part and a phase of an output of the second sensor part, a position of the magnetic sensor relative to the magnet member.

2. The position-sensing circuit of claim 1, wherein
the magnet member has a detection region which is to face the magnetic sensor,
the plurality of first magnetic poles include a first magnetic pole number of magnetic poles disposed in the detection region,
the plurality of second magnetic poles include a second magnetic pole number of magnetic poles disposed in the detection region, and
the first magnetic pole number and the second magnetic pole number are coprime.

3. The position-sensing circuit of claim 2, wherein
a difference between the first magnetic pole number and the second magnetic pole number is less than a smaller one of the first magnetic pole number and the second magnetic pole number.

4. The position-sensing circuit of claim 1, wherein
the processing circuit is configured to determine, based on a value corresponding to a difference between a first determination value based on the output of the first sensor part and a second determination value based on the output of the second sensor part, the position of the magnetic sensor relative to the magnet member.

5. The position-sensing circuit of claim 1, wherein
the first sensor part is associated with the first track, and the second sensor part is associated with the second track, and
the processing circuit is configured to determine the position of the magnetic sensor relative to the magnet member at resolution according to resolution of the output of one of the first sensor part or the second sensor part, the one of the first sensor part or the second sensor part being associated with one of the first track or the second track, the one of the first track or the second track having a smaller magnet pole pitch than the other of the first track or the second track.

6. The position-sensing circuit of claim 1, wherein
the first sensor part and the second sensor part each output a signal which is sinusoidal in an orthogonal coordinate system, the orthogonal coordinate system having a coordinate axis representing coordinates of the first sensor part and the second sensor part in the sensing direction and a coordinate axis representing the outputs of the first sensor part and the second sensor part, the coordinate axis representing the coordinates of the first sensor part and the second sensor part being orthogonal to the coordinate axis representing the outputs of the first sensor part and the second sensor part.

7. The position-sensing circuit of claim 1, wherein
the first track and the second track each have an annular shape encircling a virtual axis which is common to the first track and the second track,
at least one of the magnetic sensor or the magnet member is configured to rotationally move along the sensing direction relative to the other of the magnetic sensor or the magnet member, the sensing direction being a direction of rotation around the virtual axis, and
the processing circuit is configured to obtain, based on determination information output from a determination sensor and the information on the phase of the output of the first sensor part and the phase of the output of the second sensor part, an absolute angle of rotation of the magnetic sensor relative to the magnet member, the determination information being information based on which whether or not the absolute angle of rotation of the rotation movement is within a range from 0 to π is determined, the determination sensor being configured to generate the determination information.

8. A position-sensing system comprising:
the position-sensing circuit of claim 1;
the magnet member; and
the magnetic sensor.

9. A position-sensing system comprising:
the position-sensing circuit of claim 7;
the magnet member;
the magnetic sensor; and
the determination sensor,
the determination sensor being configured to perform a first output when the absolute angle of rotation of the rotation movement is within the range from 0 to π and otherwise perform a second output different from the first output.

10. The position-sensing system of claim 9, wherein
the magnet member includes a third track having a third magnetic pole, and
the magnetic sensor includes the determination sensor configured to sense magnetism produced at the third track.

11. The position-sensing system of claim 9, wherein
a difference between a number of first magnetic poles and a number of second magnetic poles is two.

12. The position-sensing system of claim 8, wherein
the magnet member has a linear shape.

13. The position-sensing system of claim 8, wherein
the magnet member has an arc shape or annular shape.

14. The position-sensing system of claim 8, wherein
the magnetic sensor includes a plurality of the first sensor parts and a plurality of the second sensor parts,
the plurality of first sensor parts are aligned with each other in the sensing direction, and
the plurality of second sensor parts are aligned with each other in the sensing direction.

15. The position-sensing system of claim 8, wherein
the first sensor part and the second sensor part each include an artificial lattice-type GMR element.

16. The position-sensing system of claim 15, wherein
the GMR element has a layered structure including cobalt and iron.

17. A magnet member included in the position-sensing system of claim 8.

18. A position-sensing method comprising:
a processing step of processing an output of a magnetic sensor, the magnetic sensor being configured to sense magnetism produced by a magnet member, the magnet member including a first track having a plurality of first magnetic poles and a second track having a plurality of second magnetic poles,
the plurality of first magnetic poles being magnetic poles exhibiting N polarity and magnetic poles exhibiting S polarity which are alternately aligned in a sensing direction which is prescribed, the plurality of second magnetic poles being magnetic poles exhibiting N polarity and magnetic poles exhibiting S polarity which are alternately aligned in the sensing direction,
a magnetic pole pitch of the plurality of first magnetic poles in the sensing direction being different from a magnetic pole pitch of the plurality of second magnetic poles in the sensing direction,
the magnetic sensor including a first sensor part configured to sense magnetism produced at the first track and a second sensor part configured to sense magnetism produced at the second track,
at least one of the magnetic sensor or the magnet member being configured to move along the sensing direction relative to the other of the magnetic sensor or the magnet member,
the processing step including determining, based on information on a phase of an output of the first sensor part and a phase of an output of the second sensor part, a position of the magnetic sensor relative to the magnet member.

19. A program configured to cause one or more processors to execute the position-sensing method of claim 18.
